(19) United States
(12) Patent Application Publication
(10) Pub. No.: US 2024/0215442 A1
(43) Pub. Date: Jun. 27, 2024

(54) ORGANIC LIGHT EMITTING DIODE AND ORGANIC LIGHT EMITTING DEVICE

(71) Applicant: LG Display Co., Ltd., Seoul (KR)

(72) Inventors: Byung-Geol KIM, Paju-si (KR); Seung-Hyun KIM, Paju-si (KR)

(73) Assignee: LG Display Co., Ltd., Seoul (KR)

(21) Appl. No.: 18/237,561

(22) Filed: Aug. 24, 2023

(30) Foreign Application Priority Data
Dec. 13, 2022 (KR) 10-2022-0173497

(51) Int. Cl. H10K 85/60; C09K 11/06

(52) U.S. Cl. CPC H10K 85/6572; C09K 11/06; H10K 85/615; H10K 85/654; H10K 50/13

(57) ABSTRACT

An organic light emitting diode (OLED) and an organic light emitting device comprising the OLED (e.g., a display device or a lighting device) are described. The OLED includes a red emitting material layer, a yellow-green emitting material layer and a green emitting material layer each of which includes a host with controlled charge mobility between two electrodes. The OLED and the organic light emitting device can secure wide emission area and have beneficial luminous lifespan.

### CROSS-REFERENCE TO RELATED APPLICATIONS

This application claims priority, under 35 U.S.C. § 119(a), to Korean Patent Application No. 10-2022-0173497, filed in the Republic of Korea on Dec. 13, 2022, the entire contents of which are hereby expressly incorporated by reference into the present application.

### BACKGROUND

### Technical Field

The present disclosure relates to an organic light emitting diode (OLED), and more particularly to an OLED that can be driven at low power consumption and have beneficial luminous efficiency and/or luminous luminance, as well as to an organic light emitting device including the OLED (e.g., a display device or a lighting device).

### Description of the Related Art

Flat panel display devices including an organic light emitting diode (OLED) are increasingly being used in various applications, and have various advantages over a liquid crystal display device (LCD). For instance, the OLED can be formed as a thin organic film and the electrode configurations can implement unidirectional or bidirectional images. Also, the OLED can be formed even on a flexible transparent substrate, e.g., such as a plastic substrate so that a flexible or a foldable display device can easily be provided using the OLED. In addition, the OLED can be driven at a lower voltage and the OLED has advantageous high color purity compared to an LCD.

However, there remains a need to develop OLEDs and devices thereof that have improved luminous efficiency and luminous lifespan. Since fluorescent materials use only singlet excitons in the luminous process, there is an issue with low luminous efficiency. Meanwhile, phosphorescent materials can show high luminous efficiency since they use triplet exciton as well as singlet excitons in the luminous process. But, examples of such phosphorescent material include metal complexes, which can have a luminous lifespan that is too short for commercial use. As such, there remains a need to develop an OLED and an organic light emitting device with sufficient luminous efficiency and luminous lifespan.

### SUMMARY OF THE DISCLOSURE

Embodiments of the present disclosure are directed to an organic light emitting diode and an organic light emitting device that substantially obviate one or more of the problems due to the limitations and disadvantages of the related art. An organic light-emitting diode and device thereof according to aspects of the present disclosure can operate at a low voltage, consume less power, render excellent colors, and/or can be used in a variety of applications. In an aspect, the OLED can also be formed on a flexible substrate, to provide a flexible or a foldable device. Further, the size of the OLED can be easily adjustable.

An object of the present disclosure is to provide an organic light emitting diode that can implement low power consumption and have improved luminous efficiency and luminous lifespan, as well as an organic light emitting device including the diode.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other advantages and in accordance with objects of the disclosure, as embodied and broadly described herein, in one aspect, the present disclosure provides an organic light emitting diode that includes a first electrode; a second electrode facing the first electrode; and an emissive layer disposed between the first electrode and the second electrode, and including at least one emitting part, wherein the at least one emitting part includes a red emitting material layer including a first red host; a yellow-green emitting material layer disposed between the red emitting material layer and the second electrode, and including a first yellow-green host; and a green emitting material layer disposed between the yellow-green emitting material layer and the second electrode, and including a first green host, the first red host has an electron mobility in a range between about 1E-04 cm²/V·S and about 1E-03 cm²/V·S, the first yellow-green host has a hole mobility in a range between about 5E-08 cm²/V·S and about 1E-05 cm²/V·S, and the first green host has a hole mobility in a range between about 3E-05 cm²/V·S and about 1E-4 cm²/V·S.

The first red host can include an organic compound having the following structure of Chemical Formula 1:

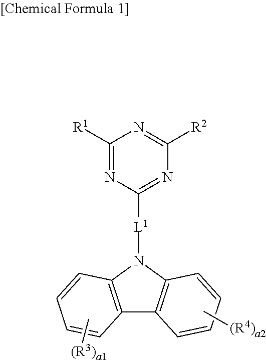

wherein, in Chemical Formula 1,
each of R¹ and R² is independently an unsubstituted or substituted C₆-C₃₀ aryl group or an unsubstituted or substituted C₃-C₃₀ hetero aryl group;
R³ is protium, deuterium or an unsubstituted or substituted C₁-C₂₀ alkyl group, where each R³ is identical to or different from each other when a1 is 2, 3 or 4;
R⁴ is independently protium, deuterium or an unsubstituted or substituted C₁₂-C₃₀ hetero aryl group having a carbazolyl moiety, wherein one of R⁴s is the unsubstituted or substituted C₁₂-C₃₀ hetero aryl group having a carbazolyl moiety;
L¹ is an unsubstituted or substituted C₆-C₃₀ arylene group;
a1 is 0, 1, 2, 3 or 4; and
a2 is 0, 1, 2, 3 or 4.

In certain aspects, in Chemical Formula 1, each of R1 and R2 is independently a moiety selected from: substituted or unsubstituted phenyl,

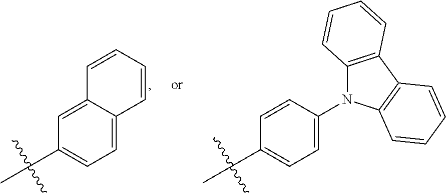 [SMILES: *c1ccc2ccccc2c1 ; *c1ccc(-n2c3ccccc3c3ccccc32)cc1]

R³ is protium or deuterium; and
R⁴ is

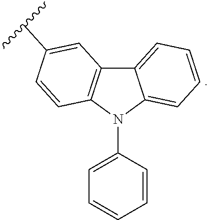 [SMILES: *c1ccc2c(c1)c1ccccc1n2-c1ccccc1]

The first yellow-green host can include an organic compound having the following structure of Chemical Formula 3:

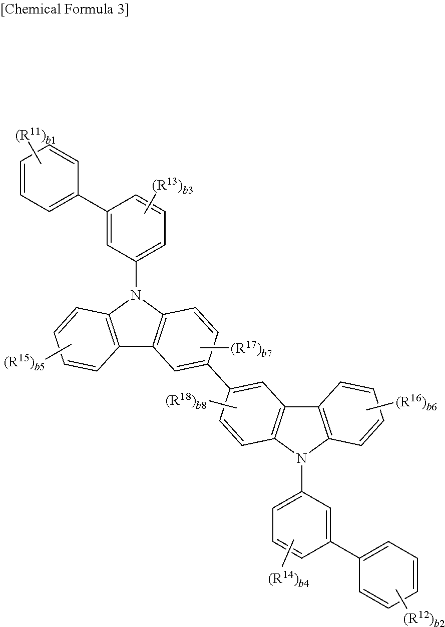

wherein, in Chemical Formula 3
each of R¹¹ to R¹⁸ is independently deuterium or an unsubstituted or substituted C₁-C₂₀ alkyl group, where at least one of R¹¹ to R¹⁸ is deuterium or a deuterium-substituted C₁-C₂₀ alkyl group, where each R¹¹ is identical to or different from each other when b1 is 2, 3, 4 or 5, where each R¹² is identical to or different from each other when b2 is 2, 3, 4 or 5, each R¹³ is identical to or different from each other when b3 is 2, 3 or 4, each R¹⁴ is identical to or different from each other when b4 is 2, 3 or 4, each R¹⁵ is identical to or different from each other when b5 is 2, 3 or 4, each R¹⁶ is identical to or different from each other when b6 is 2, 3 or 4, each R¹⁷ is identical to or different from each other when b7 is 2 or 3, and each R¹⁸ is identical to or different from each other when b8 is 2 or 3;
each of b1 and b2 is independently 0, 1, 2, 3, 4 or 5;
each of b3, b4, b5 and b6 is independently 0, 1, 2, 3 or 4; and
each of b7 and b8 is independently 0, 1, 2 or 3, where at least one of b1 to b8 is not 0.

In some aspects, in Chemical Formula 3, each of R¹¹ to R¹⁸ is independently deuterium, methyl, ethyl, propyl, iso-propyl, butyl, iso-butyl, sec-butyl, pentyl, iso-pentyl, or sec-pentyl.

The first green host can include an organic compound having the following structure of Chemical Formula 5:

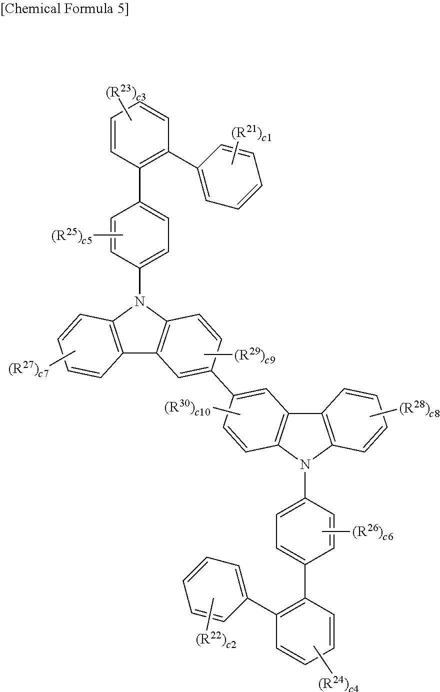

wherein, in Chemical Formula 5,
each of R²¹ to R³⁰ is independently deuterium or an unsubstituted or substituted C₁-C₂₀ alkyl group, where at least one of R² to R³⁰ is deuterium or a deuterium-substituted C₁-C₂₀ alkyl group, where each R²¹ is identical to or different from each other when c1 is 2, 3, 4 or 5, where each R²² is identical to or different from each other when c2 is 2, 3, 4 or 5, each R²³ is identical to or different from each other when c3 is 2, 3 or 4, each R²⁴ is identical to or different from each other when c4 is 2, 3 or 4, each R²⁵ is identical to or different from each other when c5 is 2, 3 or 4, each R²⁶ is identical to or different from each other when c6 is 2, 3 or 4, each R²⁷ is identical to or different from each other when c7 is 2, 3 or 4, each R²⁸ is identical to or different from each other when c8 is 2, 3 or 4, each R²⁹ is identical to or different from each other when c9 is 2 or 3, and each R³⁰ is identical to or different from each other when c0 is 2 or 3;
each of c1 and c2 is independently 0, 1, 2, 3, 4 or 5;
each of c3, c4, c5, c6, c7 and c8 is independently 0, 1, 2, 3 or 4; and
each of c9 and c10 is independently 0, 1, 2 or 3, where at least one of c1 to c10 is not 0.

In some aspects, in Chemical Formula 5, each of RV to R³⁰ is independently deuterium, methyl, ethyl, propyl, iso-propyl, butyl, iso-butyl, sec-butyl, pentyl, iso-pentyl, or sec-pentyl.

In one embodiment, the red emitting material layer can further include a second red host, and the first red host and the second red host in the red emitting material layer can be mixed with a weight ratio in a range between about 7:3 and about 5.5:4.5.

The yellow-green emitting material layer can further include a second yellow-green host, and the first yellow-green host and the second yellow-green host in the yellow-green emitting material can be mixed with a weight ratio in a range between about 6:4 and about 5:5.

The green emitting material layer can further include a second green host, and the first green host and the second green host in the green emitting material layer can mixed with a weight ratio in a range between about 6:4 and about 8:2.

The red emitting material layer can have a thickness greater than a thickness of the yellow-green emitting material layer.

The green emitting material layer can have a thickness equal to or greater than a thickness of the red emitting material layer

As an example, the emissive layer can include a first emitting part; a second emitting part disposed between the first emitting part and the second electrode; and a first charge generation layer disposed between the first emitting part and the second emitting part, and one of the first emitting part and the second emitting part can includes the red emitting material layer, the yellow-green emitting material layer and the green emitting material layer.

In another embodiment, the emissive layer can further include a third emitting part disposed between the second emitting part and the second electrode; and a second charge generation layer disposed between the second emitting part and the third emitting part.

In another aspect, the present disclosure provides an organic light emitting diode that includes a first electrode; a second electrode facing the first electrode; and an emissive layer disposed between the first electrode and the second electrode, wherein the emissive layer includes a first emitting part; a second emitting part disposed between the first emitting part and the second electrode; and a first charge generation layer disposed between the first emitting part and the second emitting part, one of the first emitting part and the second emitting part includes a first blue emitting material layer, another of the first emitting part and the second emitting part includes a red emitting material layer including a first red host; a yellow-green emitting material layer disposed between the red emitting material layer and the second electrode, and including a first yellow-green host; and a green emitting material layer disposed between the yellow-green emitting material layer and the second electrode, and including a first green host, the first red host has an electron mobility in a range between about 1E-04 cm²/V·S and about 1E-03 cm²/V·S, the first yellow-green host has a hole mobility in a range between about 5E-08 cm²/V·S and about 1E-05 cm²/V·S, and the first green host has a hole mobility in a range between about 3E-05 cm²/V·S and about 1E-4 cm²/V·S.

In one embodiment, the first emitting part can include the first blue emitting material layer, and the second emitting part can include the red emitting material layer, the yellow-green emitting material layer and the green emitting material layer.

In another embodiment, the emissive layer can further include a third emitting part disposed between the second emitting part and the second electrode; and a second charge generation layer disposed between the second emitting part and the third emitting part, the first emitting part can include the first blue emitting material layer, the second emitting part can include the red emitting material layer, the yellow-green emitting material layer and the green emitting material layer, and the third emitting part can include a second blue emitting material layer.

In yet another aspect, the present disclosure provides an organic light emitting device, for example, an organic light emitting display device or an organic light emitting illumination device that includes a substrate and the organic light emitting diode over the substrate.

In one or more embodiments, the OLED includes the red emitting material layer, the yellow-green emitting material layer and the green emitting material layer each of which includes the host with controlled charge mobility.

The first red host of an N-type red host in the red emitting material layer includes an organic compound having high electron mobility so that the emission zone is shifted toward to the red emitting material layer.

The first yellow-green host of a P-type yellow-green host in the yellow-green emitting material layer includes an organic compound having low hole mobility so that the emission zone is shifted toward to the yellow-green emitting material layer. The first green host of a P-type green host in the green emitting material layer includes an organic compound having high hole mobility so that the emission zone is shifted toward to the green emitting material layer.

Each of the red emitting material layer, the yellow-green emitting material layer and the green emitting material layer includes the host with controlled charge mobility so that the emission zone can be distributed uniformly throughout the entire emitting material layer including the red, yellow-green and green emitting material layers.

As the emission zone is distributed uniformly with the emitting material layer, exciton recombination zone can be generated with the emitting material layer. Amounts of non-emitting excitons can be minimized since the excitons are not lost outside of the emitting material layer. Excitons are not quenching as non-emission by triplet-triplet annihilation (TTA) and/or triplet-polaron annihilation (TPA).

As the exciton recombination zone is distributed uniformly throughout the entire emitting material layer without excitons biased toward particular area of the emitting material layer, the degradation of the luminous or charge transporting materials caused by excessive excitons can be prevented, and degradations of the materials caused by non-emitting excitons can be minimized.

Exciton quenching within and/or outside of the emitting material layer minimizes, and thereby, preventing driving voltage of the OLED from being raised, and therefore, the OLED can operate with low power consumption and can secure a stable lifespan of the red emission and the green emission.

It is possible to realize an OLED and an organic light emitting device having a beneficial lifespan of the red and green emission, as well as maintaining the luminous efficiency of red light, yellow-green light and green light.

It is to be understood that both the foregoing general description and the following detailed description are merely by way of example and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description, serve to explain principles of the disclosure.

FIG. 1 illustrates a schematic circuit diagram of an organic light emitting display device according to one or more embodiments of the present disclosure.

FIG. 2 illustrates a cross-sectional view of an organic light emitting display device as an example of an organic light emitting device in accordance with an embodiment of the present disclosure.

FIG. 3 illustrates a cross-sectional view of an organic light emitting diode having two emitting parts in accordance with an embodiment of the present disclosure.

FIG. 4 illustrates a schematic diagram showing energy levels of an emissive layer of an OLED where hosts without controlled charge mobility are applied.

FIG. 5 illustrates a schematic diagram showing energy levels of an emissive layer of an OLED where host with controlled charge mobility are applied.

FIG. 6 illustrates a cross-sectional view of an organic light emitting diode having two emitting parts in accordance with an example embodiment of the present disclosure.

FIG. 7 illustrates measurement result showing a current density by voltage in electron only devices (EOD) including a red host fabricated in Examples and Comparative Example.

FIG. 8 illustrates measurement result showing a current density by voltage in hole only devices (HOD) including a red host fabricated in Examples and Comparative Example.

FIG. 9 illustrates measurement result showing a current density by voltage in hole only devices (HOD) including a red host fabricated in Examples and Comparative Example.

### DETAILED DESCRIPTION OF THE EMBODIMENTS

Reference will now be made in detail to aspects of the disclosure, examples of which are illustrated in the accompanying drawings. Wherever possible, the same reference numbers will be used throughout the drawings to refer to the same or like parts. In the following description, when a detailed description of well-known functions or configurations related to this document is determined to unnecessarily cloud a gist of the inventive concept, the detailed description thereof will be or can be omitted. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations are selected only for convenience of writing the specification and can be thus different from those used in actual products. Further, all the components of each organic light emitting diode (OLED) and each organic light emitting device (e.g., display device, illumination device, etc.) using the OLED according to all embodiments of the present disclosure are operatively coupled and configured.

The present disclosure relates to an organic light emitting diode and/or an organic light emitting device where a red emitting material layer, a yellow-green emitting material layer and a green emitting material layer, each of which includes a host with controlled charge mobility, are disposed adjacently, and therefore, can maximize the luminous lifespan as well as maintain luminous efficiency emitted from each of the emitting material layers. As an example, an emissive layer can be applied to an organic light emitting diode of a tandem structure with stacking two or more emitting parts. The organic light emitting diode can be applied to an organic light emitting device such as an organic light emitting display device or an organic light emitting illumination device.

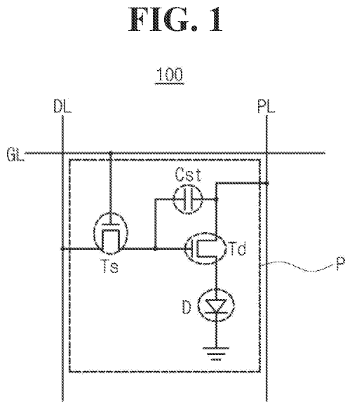

FIG. 1 illustrates a schematic circuit diagram of an organic light emitting display device in accordance with one or more embodiments of the present disclosure.

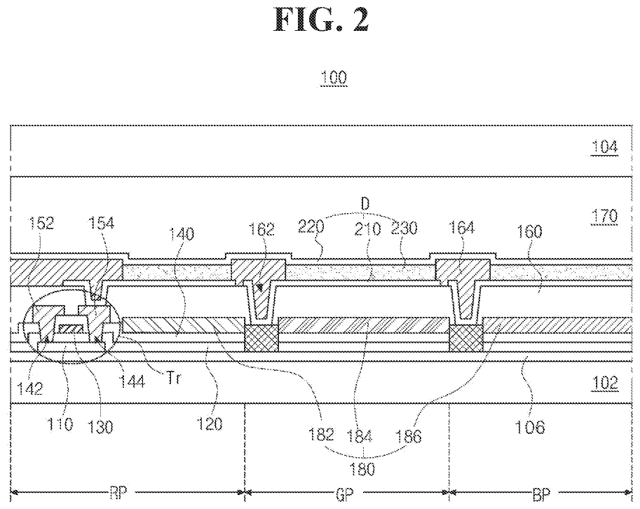

As illustrated in FIG. 1, a gate line GL, a data line DL and a power line PL, each of which crosses each other to define a pixel region P, are provided in an organic light emitting display device 100 (FIG. 2). A switching thin film transistor Ts, a driving thin film transistor Td, a storage capacitor Cst and an organic light emitting diode D are disposed within the pixel region P. The pixel region P can include a red (R) pixel region, a green (G) pixel region and a blue (B) pixel region. However, embodiments of the present disclosure are not limited to such examples. The organic light emitting display device 100 includes a plurality of such pixel regions P which can be arranged in a matrix configuration or other configurations. Further, each pixel region P can include one or more subpixels.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

The driving thin film transistor Td is turned on by the data signal applied to a gate electrode 130 (FIG. 2) so that a current proportional to the data signal is supplied from the power line PL to the organic light emitting diode D through the driving thin film transistor Td. Then the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device can display a desired image.

FIG. 2 illustrates a schematic cross-sectional view of an organic light emitting display device in accordance with an embodiment of the present disclosure. The pixel circuit configuration of FIG. 1 can be used in the display device of FIG. 2 or other figures of the present application.

As illustrated in FIG. 2, the organic light emitting display device 100 includes a first substrate 102 that defines each of a red pixel region RP, a green pixel region GP and a blue pixel region BP, a second substrate 104 facing the first substrate 102, a thin film transistor Tr on the first substrate 102, an organic light emitting diode (OLED) D disposed between the first and second substrates 102 and 104 and emitting white (W) light and a color filter layer 180 disposed between the OLED D and the first substrate 102. The organic light emitting display device 100 can include a plurality of such pixel regions arranged in a matrix configuration or other suitable configurations.

Each of the first substrate 102 and the second substrate 104 can include, but is not limited to, glass, flexible material and/or polymer plastics. For example, each of the first and second substrates 102 and 104 can be made of, but is not limited to, polyimide (PI), polyethersulfone (PES), polyethylenenaphthalate (PEN), polyethylene terephthalate (PET), polycarbonate (PC) and/or combinations thereof. The first substrate 102, on which a thin film transistor Tr and the OLED D are arranged, forms an array substrate. In certain embodiments, the second substrate 104 can be omitted.

A buffer layer 106 can be disposed on the first substrate 102. The thin film transistor Tr can be disposed on the buffer layer 106 correspondingly to each of the red pixel region RP, the green pixel region GP and the blue pixel region BP. In certain embodiments, the buffer layer 106 can be omitted.

A semiconductor layer 110 is disposed on the buffer layer 106. In one embodiment, the semiconductor layer 110 can include, but is not limited to, oxide semiconductor materials. In this case, a light-shield pattern can be disposed under the semiconductor layer 110, and the light-shield pattern can prevent light from being incident toward the semiconductor layer 110, thereby, preventing or reducing the semiconductor layer 110 from being degraded by the light. Alternatively, the semiconductor layer 110 can include polycrystalline silicon. In this case, opposite edges of the semiconductor layer 110 can be doped with impurities.

A gate insulating layer 120 including an insulating material is disposed on the semiconductor layer 110. The gate insulating layer 120 can include, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on the entire area of the substrate 102 as shown in FIG. 2, the gate insulating layer 120 can be patterned identically as the gate electrode 130.

An interlayer insulating layer 140 including an insulating material is disposed on the gate electrode 130 and covers an entire surface of the substrate 102. The interlayer insulating layer 140 can include, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

The interlayer insulating layer 140 has first and second semiconductor layer contact holes 142 and 144 that expose or do not cover a portion of the surface nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 and the interlayer insulating layer 140 in FIG. 2. Alternatively, in certain embodiments, the first and second semiconductor layer contact holes 142 and 144 can be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can include amorphous silicon. Here, the designation of the source and drain electrodes 152 and 154 can be switched with each other depending on the type and configuration of a transistor.

The gate line GL and the data line DL, which cross each other to define a pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL. The thin film transistor Tr can further include a storage capacitor Cst configured to constantly keep a voltage of the gate electrode 130 for one frame.

A passivation layer 160 is disposed on the source and drain electrodes 152 and 154 and covers the thin film transistor Tr over the whole first substrate 102. The passivation layer 160 has a flat top surface and a drain contact hole (or a contact hole) 162 that exposes or does not cover the drain electrode 154 of the thin film transistor Tr. While the drain contact hole 162 is disposed on the second semiconductor layer contact hole 144, it can be spaced apart from the second semiconductor layer contact hole 144.

The organic light emitting diode (OLED) D includes a first electrode 210 that is disposed on the passivation layer 160 and connected to the drain electrode 154 of the thin film transistor Tr. The OLED D further includes an emissive layer 230 and a second electrode 220 each of which is disposed sequentially on the first electrode 210.

The first electrode 210 is formed for each pixel region RP, GP or BP. The first electrode 210 can be an anode and include conductive material having relatively high work function value. For example, the first electrode 210 can include a transparent conductive oxide (TCO). In an embodiment, the first electrode 210 can include, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or combinations thereof.

In one embodiment, when the organic light emitting display device 100 is a bottom-emission type, the first electrode 210 can have a single-layered structure of the TCO.

In addition, a bank layer 164 is disposed on the passivation layer 160 in order to cover edges of the first electrode 210. The bank layer 164 exposes or does not cover a center of the first electrode 210 corresponding to each of the red pixel region RP, the green pixel region GP and the blue pixel region BP. In certain embodiments, the bank layer 164 can be omitted.

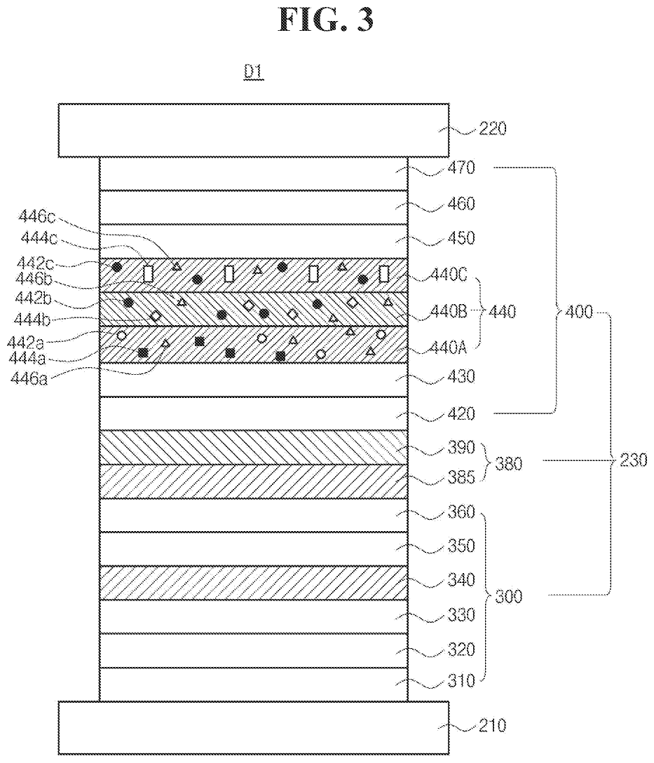

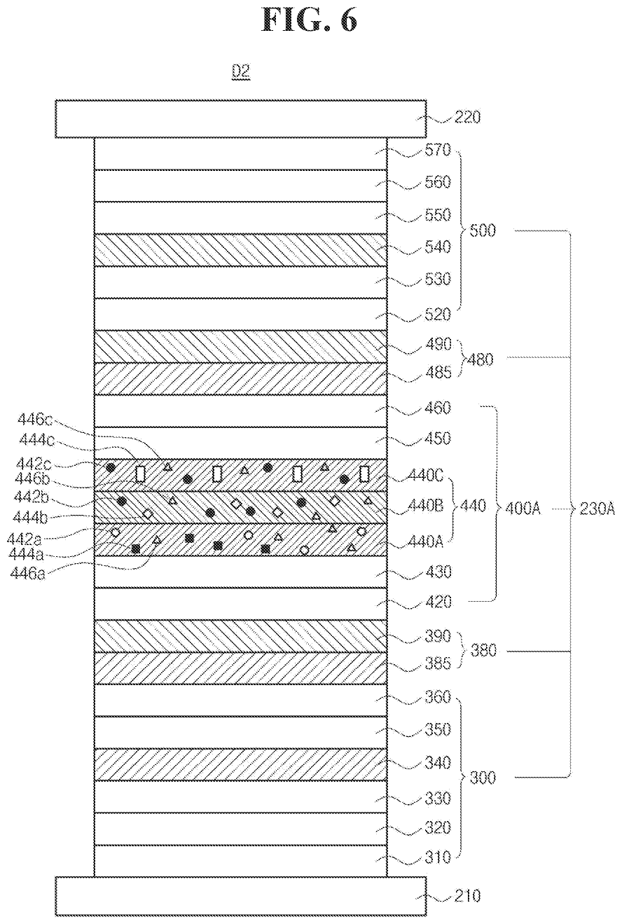

The emissive layer 230 is disposed on the first electrode 210. The emissive layer 230 can include at least one emitting part. For example, as illustrated in FIGS. 3 and 6, the emissive layer 230 can include a plurality of emitting parts 300, 400, 400A and 500 and a plurality of charge generation layers 380 and 480. In one embodiment, each of the emitting parts 300, 400, 400A and 500 can have a single-layered structure of an emitting material layer (EML).

In another embodiment, each of the emitting parts 300, 400, 400A and 500 in the emissive layer 230 can have a multiple-layered structure of a hole injection layer (HIL), a hole transport layer (HTL), an electron blocking layer (EBL), an EML, a hole blocking layer (HBL), an electron transport layer (ETL), an electron injection layer (EIL).

The emissive layer 230 can have a single emitting part. Alternatively, the emissive layer 230 can have multiple emitting parts to form a tandem structure. For example, the emissive layer 230 can be applied into an organic light emitting diode having a single emitting part located at each of the red pixel region RP, the green pixel region GP and the blue pixel region BP. In another embodiment, the emissive layer 230 can be applied to an organic light emitting diode of a tandem structure stacked multiple emitting parts, located at each of the red pixel region RP, the green pixel region GP and the blue pixel region BP.

The emissive layer 230 can include a red emitting material layer, a yellow-green emitting material layer and a green emitting material layer each of which includes a different host with controlled charge mobility.

The second electrode 220 is disposed on the first substrate 102 above which the emissive layer 230 is disposed. The second electrode 220 can be disposed on the entire display area. The second electrode 220 can include a conductive material with a relatively low work function value compared to the first electrode 210. The second electrode 220 can be a cathode providing electrons. For example, the second electrode 220 can include a highly reflective material such as aluminum (Al), magnesium (Mg), calcium (Ca), silver (Ag), alloy thereof and/or combinations thereof such as aluminum-magnesium alloy (Al—Mg).

In addition, an encapsulation film 170 can be disposed on the second electrode 220 in order to prevent or reduce outer moisture from penetrating into the OLED D. The encapsulation film 170 can have, but is not limited to, a laminated structure of a first inorganic insulating film, an organic insulating film and a second inorganic insulating film. In certain embodiments, the encapsulation film 170 can be omitted.

The organic light emitting display device 100 can further include a polarizing plate to reduce reflection of external light. For example, the polarizing plate can be a circular polarizing plate. When the organic light emitting display device 100 is a bottom-emission type, the polarizing plate can be disposed under the first substrate 102. When the organic light emitting display device 100 is a top-emission type, the polarizing plate can be disposed on the encapsulation film 170 or the second electrode 220. In addition, a cover window can be attached to the encapsulation film 170 or the polarizing plate. In this case, the first substrate 102, the second substrate 104 and the cover window can have a flexible property, thus the organic light emitting display device 100 can be a flexible display device.

The color filter layer 180 can be disposed between the first substrate 102 and the OLED D, for example, between the interlayer insulating layer 140 and the passivation layer 160. The color filter layer 180 can include a red color filter pattern 182, a green color filter pattern 184 and a blue color filter pattern 186 each of which is disposed correspondingly to the red pixel region RP, the green pixel region GP and the blue pixel region BP, respectively.

In the organic light emitting display device 100, the light emitted from the emissive layer 230 is incident to the color filter layer 180 through the first electrode 210, and the color filter layer 180 is disposed under OLED D. The organic light emitting display device 100 can be a bottom-emission type. Alternatively, when the organic light emitting display device 100 is a top-emission type, the light emitted from the OLED D is transmitted through the second electrode 220, and the color filter layer 180 can be disposed on the OLED D. In one embodiment, the color filter layer 180 can be attached to the OLED D by adhesive layer. Alternatively or additionally, the color filter layer 180 can be disposed directly on the OLED D.

In one embodiment, when the organic light emitting display device 100 is a top-emission type, a reflector or a reflective layer can be disposed under the first electrode 210. For example, the reflector or the reflective layer can include, but is not limited to, silver (Ag) or aluminum-palladium-copper (APC) alloy.

In addition, a color conversion layer can be formed or disposed between the OLED D and the color filter layer 180. The color conversion layer can include a red color conversion layer, a green color conversion layer and a blue color conversion layer each of which is disposed correspondingly to each pixel region (RP, GP and BP), respectively, so as to convert the white (W) color light to each of a red, green and blue color lights, respectively. For example, the color conversion layer can include quantum dots so that the color purity of the organic light emitting display device 100 can be further improved. Alternatively, the organic light emitting display device 100 can comprise the color conversion layer instead of the color filter layer 180.

The OLED D with plural emitting parts is described in more detail. FIG. 3 illustrates a schematic cross-sectional view of an organic light emitting diode having two emitting parts in accordance with an embodiment of the present disclosure. For instance, FIG. 3 shows an example (OLED D) of the OLED D in FIGS. 1 and 2.

As illustrated in FIG. 3, the organic light emitting diode (OLED) D1 in accordance with an example of the present disclosure includes a first electrode 210, a second electrode 220 facing the first electrode 210 and an emissive layer 230 disposed between the first electrode 210 and the second electrode 220. The organic light emitting display device 100 includes the red pixel region RP, the green pixel region GP and the blue pixel region BP, and the OLED D1 can be disposed in the red pixel region RP, the green pixel region GP and the blue pixel region BP.

The first electrode 210 can be an anode and can include conductive material with relatively high work function value, such as TCO. In one embodiment, the first electrode can include, but is not limited to, ITO, IZO, ITZO, SnO, ZnO, ICO and/or AZO. The second electrode 220 can be a cathode and can include conductive material with relatively low work function value. The second electrode 220 can include highly reflective material such as Al, Mg, Ca, Ag, alloy thereof and/or combinations thereof.

The emissive layer 230 includes a first emitting part 300 disposed between the first electrode 210 and the second electrode 220, a second emitting part 400 disposed between the first emitting part 300 and the second electrode 220 and a charge generation layer (CGL) 380 disposed between the first emitting part 300 and the second emitting part 400.

The first emitting part 300 includes a first emitting material layer (EML1) 340. The first emitting part 300 can include at least one of a first hole transport layer (HTL1) 320 disposed between the first electrode 210 and the EML1 340 and a first electron transport layer (ETL1) 360 disposed between the EML1 340 and the CGL 380. The first emitting part 300 can further include a hole injection layer (HIL) 310 disposed between the first electrode 210 and the HTL1 320. Alternatively or additionally, the first emitting part 300 can further include at least one of a first electron blocking layer (EBL1) 330 disposed between the HTL1 320 and the EML1 340 and a first hole blocking layer (HBL1) 350 disposed between the EML1 340 and the ETL1 360.

The second emitting part 400 includes a second emitting material layer (EML2) 440. The second emitting part 400 can include at least one of a second hole transport layer (HTL2) 420 disposed between the CGL 380 and the EML2 440 and a second electron transport layer (ETL2) 460 disposed between the EML2 440 and the second electrode 220. The second emitting part 400 can further include an electron injection layer (EIL) 470 disposed between the ETL2 460 and the second electrode. Alternatively or additionally, the second emitting part 400 can further include at least one of a second electron blocking layer (EBL2) 430 disposed between the HTL2 420 and the EML2 440 and a second hole blocking layer (HBL2) 450 disposed between the EML2 440 and the ETL2 460.

In one embodiment, one of the EML1 340 and the EML2 440 can emit blue color light and the other of the EML1 340 and the EML2 440 can emit red, yellow-green and green color lights. Hereinafter, the OLED D1 where the EML1 340 emits blue color light and the EML2 440 emits red, yellow-green and green color lights will be described in detail.

The EML2 440 can include a red emitting material layer (R-EML, first layer) 440A, a yellow-green emitting material layer (YG-EML, second layer) 440B and a green emitting material layer (G-EML, third layer) 440C disposed sequentially between the CGL 380 and the second electrode 220, for example, the HTL2 420 or the EBL2 430 and the ETL2 460 or the HBL2 450.

The first layer 440A includes a first red host 442a, a red emitter (red dopant) 446a, and optionally, a second red host 444a. The second layer 440B includes a first yellow-green host 442b, a yellow-green emitter (yellow-green dopant) 446b, and optionally, a second yellow-green host 444b. The third layer 440C includes a first green host 442c, a green emitter (green dopant) 446c, and optionally, a second green host 444c.

The first red host 442a can be an N-type (electron type) host with relatively strong electron affinity property. The first yellow-green host 442b can be a P-type (hole type) host with relatively weak hole affinity property. The first green host 442c can be a P-type host with relatively strong hole affinity property. Each of the first layer 440A, the second layer 440B and the third layer 440C includes a different host with controlled charge affinity property, or charge mobility, and thus, the luminous efficiency and the luminous lifespan of the OLED D1 can be improved.

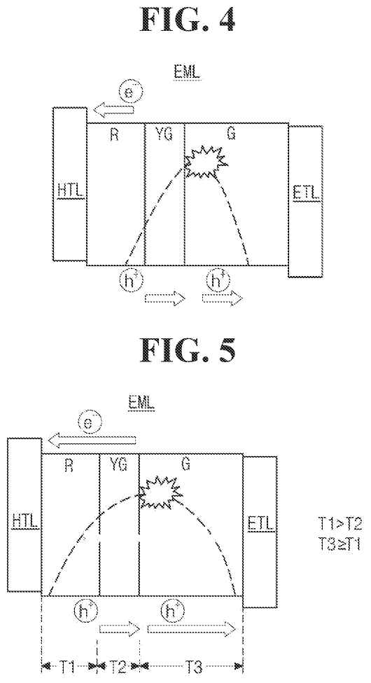

FIG. 4 illustrates a schematic diagram showing energy levels of an emissive layer of an OLED where hosts without controlled charge mobility are applied. As illustrated in FIG. 4, the first red host has a relatively slow electron mobility, the first yellow-green host has a relatively fast hole mobility and the first green host has a relatively slow hole mobility. Holes injected to the EML2 440 from the HTL2 420 and electrons injected to the EML2 440 from the ETL2 460 are mostly recombined at the G-EML 440C to generate excitons. In this case, exciton recombination zone is concentrated at a narrow area of the G-EML 440C among the entire EML2 440, so that the luminous materials in the G-EML 440C where the excitons are concentrated can be deteriorated.

In addition, considerable amounts of holes and electrons injected into the EML 440 cannot generate excitons which emit light, being non-radiative quenching. The non-radiative quenched excitons interact with the luminous materials in the R-EML 440A spaced apart from the recombination zone among the EML2 440, the charge transporting materials in the HTL2 420 and/or the ETL2 460. The luminous material in the R-EML 440A and/or the charge transporting materials in the HTL2 420 and/or the ETL2 460 can be degraded owing to the interactions with the non-radiative quenched excitons, and therefore, the luminous properties, particularly, the luminous lifespan, of the organic light emitting diode is lowered considerably.

FIG. 5 illustrates a schematic diagram showing energy levels of an emissive layer of an OLED where host with controlled charge mobility are applied. Comparing FIG. 5 to FIG. 4, the electron mobility of the first red host is relatively fast, the hole mobility of the first yellow-green host is relatively slow and the hole mobility of the first green host is relatively fast. Holes injected into the EML2 440 from the HTL2 420 and electrons injected into the EML2 440 from the ETL2 460 are recombined in the entire area of the EML2 440 including the R-EML 440A, the YG-EML 440B and the G-EML 440C to generate excitons. The exciton recombination zone is distributed uniformly in the entire EML2 440.

As excitons are generated uniformly in the entire area of the R-EML 440A, the YG-EML 440B and the G-EML 440C, the degradations of the luminous materials in the EML2 440 caused by the excessive exciton generations can be minimized. The holes and electrons injected into the EML2 440 generates excitons within the EML2 440 to emit light, the amount of excitons with non-radiative quenching can be minimized.

Accordingly, the non-radiative quenching excitons hardly interact with the luminous materials in the EML2 440 and/or the charge transporting materials in the HTL2 420 and/or the ETL2 460, so that the degradations of the luminous materials in the EML 4402 and/or the charge transporting materials in the HTL2 420 and/or the ETL2 460 caused by the interactions with the non-radiative quenching excitons are minimized, and therefore, the luminous properties such as luminous lifespan of the OLED D1 can be improved significantly.

In one embodiment, the R-EML 440A can have a thickness T1 greater than a thickness T2 of the YG-EML 440B. In another embodiment, the G-EML 440C can have a thickness T3 equal to or greater than the thickness T1 of the R-EML 440A. In this case, as the amount of the yellow-green color, which is not pure color light, it is possible to implement white (W) emission with beneficial color purity.

For example, the R-EML 440A can have the thickness T1 in a range between about 100 Å and about 200 Å, the YG-EML 440B can have the thickness T2 in a range between about 80 Å and about 120 Å, and the G-EML 440C can have the thickness T3 in a range between about 250 Å and about 300 Å, but is not limited thereto. In certain aspects, the R-EML 440A can have the thickness T1 in a range between about 110 Å and about 190 Å, about 120 Å and about 180 Å, about 130 Å and about 170 Å, about 140 Å and about 160 Å, or about 150 Å. In certain aspects, the YG-EML 440B can have the thickness T2 in a range between about 85 Å and about 115 Å, about 90 Å and about 110 Å, about 95 Å and about 110 Å, or about 100 Å. In certain aspects, the G-EML 440C can have the thickness T3 in a range between about 255 Å and about 295 Å, about 260 Å and about 290 Å, about 270 Å and about 280 Å, or about 275 Å.

With returning to FIG. 3, the first red host 442a in the first layer 440A can have electron mobility in a range between about 1E-04 cm²/V·S and about 1E-03 cm²/V·S. The first red host 442a in the first layer 440A can be an N-type red host. As an example, the first red host 442a can include, but is not limited to, an organic compound having the following structure of Chemical Formula 1:

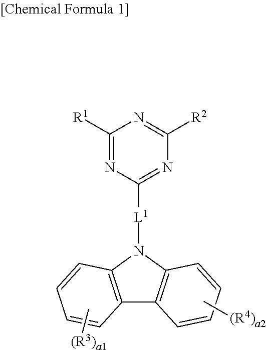

wherein, in Chemical Formula 1,
each of R¹ and R² is independently an unsubstituted or substituted C₆-C₃₀ aryl group or an unsubstituted or substituted C₃-C₃₀ hetero aryl group;
R³ is protium, deuterium or an unsubstituted or substituted C₁-C₂₀ alkyl group, where each R³ is identical to or different from each other when a1 is 2, 3 or 4;
R⁴ is each independently protium, deuterium or an unsubstituted or substituted C₁₂-C₃₀ hetero aryl group having a carbazolyl moiety, wherein one of R's is the unsubstituted or substituted C₁₂-C₃₀ hetero aryl group having a carbazolyl moiety
a1 is 0, 1, 2, 3 or 4; and
a2 is 0, 1, 2, 3 or 4.

As used herein, the term “unsubstituted” means that hydrogen is directly linked to a carbon atom. “Hydrogen”, as used herein, can refer to protium.

As used herein, “substituted” means that the hydrogen is replaced with a substituent. The substituent can comprise, but is not limited to, deuterium, an unsubstituted or deuterium- or halogen-substituted C₁-C₂₀ alkyl group, an unsubstituted or deuterium- or halogen-substituted C₁-C₂₀ alkoxy, halogen, a cyano group, a hydroxyl group, a carboxylic group, a carbonyl group, an amino group, an unsubstituted or deuterium-substituted C₁-C₁₀ alkyl amino group, an unsubstituted or deuterium-substituted C₆-C₃₀ aryl amino group, an unsubstituted or deuterium-substituted C₃-C₃₀ hetero aryl amino group, a nitro group, a hydrazyl group, a sulfonate group, an unsubstituted or deuterium- or halogen-substituted C₁-C₁₀ alkyl silyl group, an unsubstituted or deuterium- or halogen-substituted C₁-C₁₀ alkoxy silyl group, an unsubstituted or deuterium- or halogen-substituted C₃-C₂₀ cyclo alkyl silyl group, an unsubstituted or deuterium- or halogen-substituted C₆-C₃₀ aryl silyl group, an unsubstituted or deuterium- or halogen-substituted C₃-C₃₀ hetero aryl silyl group, an unsubstituted or deuterium- or alkyl-substituted C₆-C₃₀ aryl group, an unsubstituted or deuterium- or alkyl-substituted C₃-C₃₀ hetero aryl group.

For example, the substituent of the C₆-C₃₀ aryl group and the C₃-C₃₀ hetero aryl group can include at least one of a C₁-C₂₀ alkyl group, a C₆-C₃₀ aryl group and a C₃-C₃₀ hetero aryl group.

As used herein, the term “hetero” in terms such as “a hetero aromatic group”, “a hetero cyclo alkylene group”, “a hetero arylene group”, “a hetero aryl alkylene group”, “a hetero aryl oxylene group”, “a hetero cyclo alkyl group”, “a hetero aryl group”, “a hetero aryl alkyl group”, “a hetero aryloxy group”, “a hetero aryl amino group” and the likes means that at least one carbon atom, for example 1 to 5 carbons atoms, constituting an aliphatic chain, an alicyclic group or ring or an aromatic group or ring is substituted with at least one hetero atom selected from the group consisting of N, O, S and P.

As used herein, the C₆-C₃₀ aryl group can include, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl.

As used herein, the C₃-C₃₀ hetero aryl group can include, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl.

For example, each of R¹ and R² in Chemical Formula 1 can be independently an unsubstituted or substituted C₆-C₃₀ aryl group. In one embodiment, each of the C₆-C₃₀ aryl group and the C₃-C₃₀ hetero aryl group of R¹ and R² and the C₁₂-C₃₀ hetero aryl group of R⁴ can be independently unsubstituted or substituted with deuterium, an unsubstituted or deuterium-substituted C₆-C₃₀ aryl group and/or an unsubstituted or deuterium-substituted C₃-C₃₀ hetero aryl group.

In another embodiment, R¹ can be unsubstituted or deuterium-substituted phenyl, R² can be phenyl or naphthyl, which is independently unsubstituted or substituted with deuterium or C₃-C₃₀ hetero aryl (e.g., carbazolyl), L¹ may be a phenylene which is unsubstituted or substituted with deuterium, R³ can be protium or deuterium, and R⁴ can be deuterium or unsubstituted or phenyl-substituted carbazolyl where a moiety other than a linking position to the phenyl can be unsubstituted or substituted with deuterium, but is not limited thereto.

As an example, each of the aryl group and the hetero aryl group can consist of one to three aromatic and/or hetero aromatic rings. When the number of the aromatic and/or hetero aromatic rings of the aryl group and the hetero aryl group becomes more than four, conjugated structure within the whole molecule becomes too long, thus, the organometallic compound can have too narrow energy bandgap. For example, each of the aryl group or the hetero aryl group can comprise independently, but is not limited to, phenyl, biphenyl, naphthyl, anthracenyl, pyrrolyl, triazinyl, imidazolyl, pyrazolyl, pyridinyl, pyrazinyl, pyrimidinyl, pyridazinyl, furanyl, benzo-furanyl, dibenzo-furanyl, thiophenyl, benzo-thiophenyl, dibenzo-thiophenyl, carbazolyl, acridinyl, carbolinyl, phenazinyl, phenoxazinyl, or phenothiazinyl.

For example, the first red host 442a can be, but is not limited to, at least one of the following organic compounds of Chemical Formula 2:

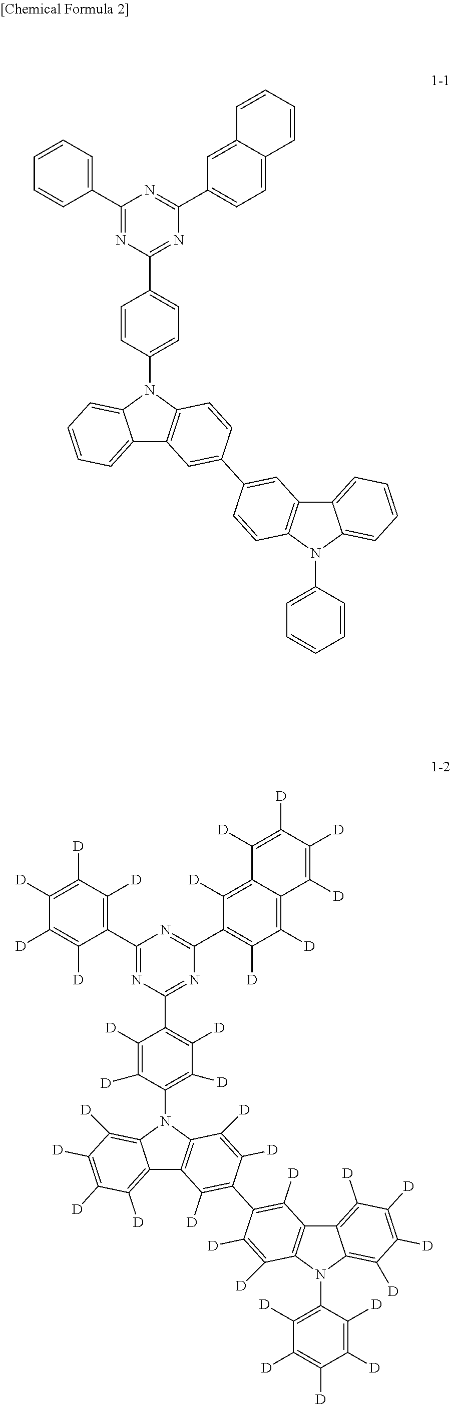 [SMILES: c1ccc(-c2nc(-c3ccc(-n4c5ccccc5c5cc(-c6ccc7c(c6)c6ccccc6n7-c6ccccc6)ccc54)cc3)nc(-c3ccc4ccccc4c3)n2)cc1 ; [2H]c1c([2H])c([2H])c(-c2nc(-c3c([2H])c([2H])c(-n4c5c([2H])c([2H])c([2H])c([2H])c5c5c([2H])c(-c6c([2H])c([2H])c7c(c6[2H])c6c([2H])c([2H])c([2H])c([2H])c6n7-c6c([2H])c([2H])c([2H])c([2H])c6[2H])c([2H])c([2H])c54)c([2H])c3[2H])nc(-c3c([2H])c([2H])c4c([2H])c([2H])c([2H])c([2H])c4c3[2H])n2)c([2H])c1[2H]]

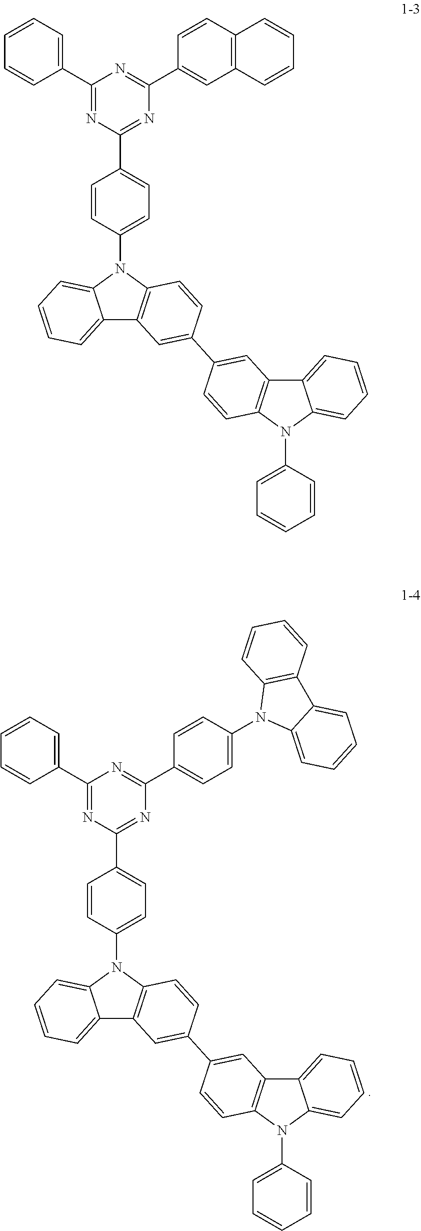 [SMILES: c1ccc(-c2nc(-c3ccc(-n4c5ccccc5c5cc(-c6ccc7c(c6)c6ccccc6n7-c6ccccc6)ccc54)cc3)nc(-c3ccc4ccccc4c3)n2)cc1 ; c1ccc(-c2nc(-c3ccc(-n4c5ccccc5c5ccccc54)cc3)nc(-c3ccc(-n4c5ccccc5c5cc(-c6ccc7c(c6)c6ccccc6n7-c6ccccc6)ccc54)cc3)n2)cc1]

The first yellow-green host 442b in the second layer 440B can have hole mobility in a range between about 5E-08 cm²/V·S and about 1E-05 cm²/V·S. The first yellow-green host 442b in the second layer 440B can be a P-type yellow-green host. As an example, the first yellow-green host 442b can include, but is not limited to, an organic compound having the following structure of Chemical Formula 3:

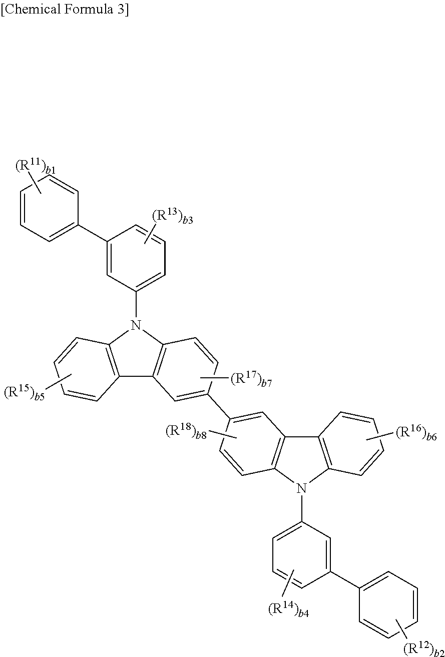

wherein, in Chemical Formula 3:
each of R¹¹ to R¹⁸ is independently deuterium or an unsubstituted or substituted C₁-C₂₀ alkyl group, where at least one of R¹¹ to R^{1S} is deuterium or a deuterium-substituted C₁-C₂₀ alkyl group, where each R¹¹ is identical to or different from each other when b1 is 2, 3, 4 or 5, where each R¹² is identical to or different from each other when b2 is 2, 3, 4 or 5, each R¹³ is identical to or different from each other when b3 is 2, 3 or 4, each R¹⁴ is identical to or different from each other when b4 is 2, 3 or 4, each R¹⁵ is identical to or different from each other when b5 is 2, 3 or 4, each R¹⁶ is identical to or different from each other when b6 is 2, 3 or 4, each R¹⁷ is identical to or different from each other when b7 is 2 or 3, and each R¹⁸ is identical to or different from each other when b8 is 2 or 3;
each of b1 and b2 is independently 0, 1, 2, 3, 4 or 5;
each of b3, b4, b5 and b6 is independently 0, 1, 2, 3 or 4; and
each of b7 and b8 is independently 0, 1, 2 or 3, where at least one of b1 to b8 is not 0. In one example, the organic compound represented by the Chemical Formula 3 has at least one substituent which is deuterium or a deuterium-substituted C₁-C₂₀ alkyl group.

For example, the first yellow-green host 442b can be, but is not limited to, the following organic compound of Chemical Formula 4:

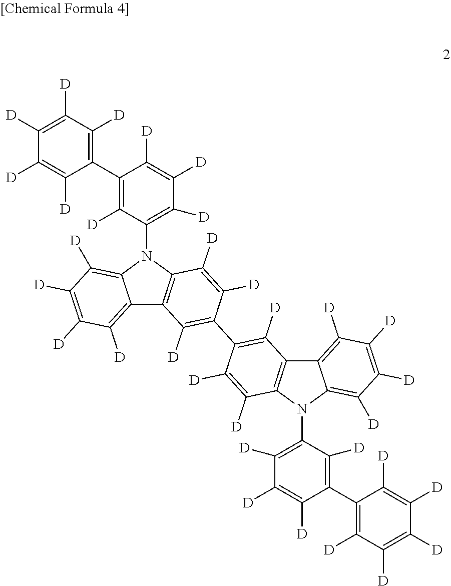 [SMILES: [2H]c1c([2H])c([2H])c(-c2c([2H])c([2H])c([2H])c(-n3c4c([2H])c([2H])c([2H])c([2H])c4c4c([2H])c(-c5c([2H])c([2H])c6c(c5[2H])c5c([2H])c([2H])c([2H])c([2H])c5n6-c5c([2H])c([2H])c([2H])c(-c6c([2H])c([2H])c([2H])c([2H])c6[2H])c5[2H])c([2H])c([2H])c43)c2[2H])c([2H])c1[2H]]

The first green host 442c in the third layer 440C can have hole mobility in a range between about 3E-05 cm²/V·S and about 1E-04 cm²/V·S. The first green host 442c in the third layer 440C can be a P-type green host. As an example, the first green host 442c can include, but is not limited to, an organic compound having the following structure of Chemical Formula 5:

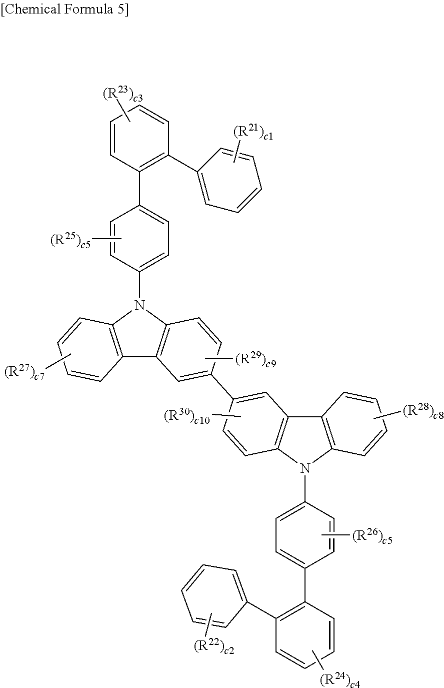

wherein, in Chemical Formula 5,
each of R²¹ to R³⁰ is independently deuterium or an unsubstituted or substituted C₁-C₂₀ alkyl group, where at least one of R²¹ to R³⁰ is deuterium or a deuterium-substituted C₁-C₂₀ alkyl group, where each R²¹ is identical to or different from each other when c1 is 2, 3, 4 or 5, where each R²² is identical to or different from each other when c2 is 2, 3, 4 or 5, each R²³ is identical to or different from each other when c3 is 2, 3 or 4, each R²⁴ is identical to or different from each other when c4 is 2, 3 or 4, each R²⁵ is identical to or different from each other when c5 is 2, 3 or 4, each R²⁶ is identical to or different from each other when c6 is 2, 3 or 4, each R²⁷ is identical to or different from each other when c7 is 2, 3 or 4, each R²⁸ is identical to or different from each other when c8 is 2, 3 or 4, each R²⁹ is identical to or different from each other when c9 is 2 or 3, and each R³¹ is identical to or different from each other when c10 is 2 or 3;
each of c1 and c2 is independently 0, 1, 2, 3, 4 or 5;
each of c3, c4, c5, c6, c7 and c8 is independently 0, 1, 2, 3 or 4; and
each of c9 and c10 is independently 0, 1, 2 or 3, where at least one of c1 to c10 is not 0.

In one example, the organic compound represented by the Chemical Formula 5 has at least one substituent which is deuterium or a deuterium-substituted C₁-C₂₀ alkyl group.

For example, the first green host 442c can be, but is not limited to, the following organic compound of Chemical Formula 6:

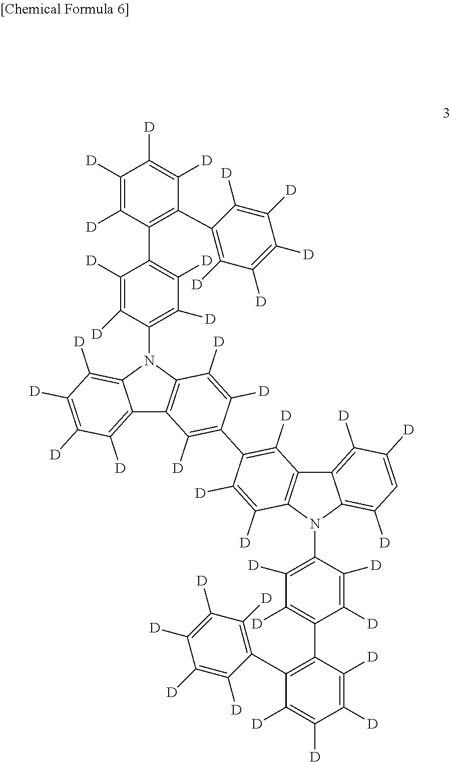 [SMILES: [2H]c1cc([2H])c2c(c1[2H])c1c([2H])c(-c3c([2H])c([2H])c4c(c3[2H])c3c([2H])c([2H])c([2H])c([2H])c3n4-c3c([2H])c([2H])c(-c4c([2H])c([2H])c([2H])c([2H])c4-c4c([2H])c([2H])c([2H])c([2H])c4[2H])c([2H])c3[2H])c([2H])c([2H])c1n2-c1c([2H])c([2H])c(-c2c([2H])c([2H])c([2H])c([2H])c2-c2c([2H])c([2H])c([2H])c([2H])c2[2H])c([2H])c1[2H]]

The first layer 440A can further include the second red host 444a. The second red host 444a can be a P-type or bipolar red host with relatively strong hole affinity property compared to the first red host 442a. As an example, the second red host 444a can include, but is not limited to, a carbazole-containing organic compound, an aryl amine-containing organic compound, a hetero aryl amine-containing organic compound and a spirofluorene-containing organic compound.

For example, the second red host 444a can include, but is not limited to, 4,4′-bis(N-carbazolyl)-1,1′-biphenyl (CBP), 3,3′-bis(N-carbazolyl)-1,1′-biphenyl (mCBP), 1,3-bis(carbazol-9-yl)benzene (mCP), 2,8-bis(diphenylphosphoryl)dibenzothiophene (PPT), 2,8-di(9H-carbazol-9-yl)dibenzothiophene (DCzDBT), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicarbazole, 9,9′-Diphenyl-9H,9′H-3,3′-bicarbazole (BCzPh), 9,9′-di(4-biphenyl)-9H,9′H-3,3′-bicarbazole (BCZ), 1,3,5-Tris(carbazol-9-yl)benzene (TCP), Tris(4-carbazoyl-9-yl-phenyl)amine (TCTA), 4,4′-Bis(carbazole-9-yl)-2,2′-dimethylbiphenyl (CDBP), 2,7-Bis(carbazole-9-yl)-9,9-dimethylfluorene (DMFL-CBP), 2,2′,7,7′-Tetrakis(carbazol-9-yl)-9,9-spirofluorene (Spiro-CBP), 3,6-Bis(carbazole-9-yl)-9-(2-ethyl-hexyl)-9H-carbazole (TCzl), the organic compound of the following Chemical Formula 7 and/or combinations thereof.

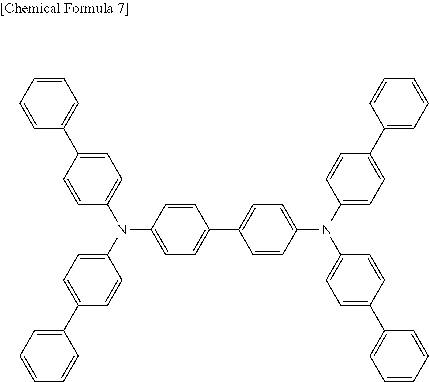 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

In another embodiment, the second red host 444a can include at least one of a hole injecting material, a hole transporting material and an electron blocking material as described below.

The red emitter 446a can include at least one of a red phosphorescent material, a red fluorescent material and a red delayed fluorescent material. For example, the red emitter 446a can include, but is not limited to, Bis[2-(4,6-dimethyl)phenylquinoline)](2,2,6,6-tetramethylheptane-3,5-dionate)iridium(III), Bis[2-(4-n-hexylphenyl)quinoline](acetylacetonate)iridium(III) (Hex-Ir(phq)₂(acac)), Tris[2-(4-n-hexylphenyl)quinoline]iridium(III) (Hex-Ir(phq)₃), Tris[2-phenyl-4-methylquinoline]iridium(II) (Ir(Mphq)₃), Bis(2-phenylquinoline)(2,2,6,6-tetramethylheptene-3,5-dionate)iridium(III) (Ir(dpm)PQ₂), Tris(1-phenylisoquinoline)iridium(III) (Ir(piq)₃), Bis(phenylisoquinoline)(2,2,6,6-tetramethylheptene-3,5-dionate)iridium(III) (Ir(dpmxpiq)₂), Bis(1-phenylisoquinoline)(acetylacetonate)iridium(III) (Ir(piq)₂(acac)), Bis[(4-n-hexylphenyl)isoquinoline](acetylacetonate)iridium(III) (Hex-Ir(piq)₂(acac)), Tris[2-(4-n-hexylphenyl)quinoline]iridium(III) (Hex-Ir(piq)₃), Tris(2-(3-methylphenyl)-7-methyl-quinolato)iridium (Ir(dmpq)₃), Bis[2-(2-methylphenyl)-7-methyl-quinoline](acetylacetonate)iridium(III) (Ir(dmpq)₂(acac)), Bis[2-(3,5-dimethylphenyl)-4-methyl-quinoline](acetylacetonate)iridium(III) (Ir(mphmq)₂(acac)), Tris(dibenzoylmethane)mono(1,10-phenanthroline)europium(III) (Eu(dbm) (phen)), and/or combinations thereof.

As an example, the contents of the red host including the first red host 442a and the second red host 444a in the first layer 440A can be about 50 wt. % to about 99 wt. %, for example, about 80 wt. % to about 95 wt. %, and the contents of the red emitter 446a in the first layer 440A can be about 1 wt. % to about 50 wt. %, for example, about 5 wt. % to about 20 wt. %, but is not limited thereto. When the first layer 440A includes both the first red host 442a and the second red host 444a, the contents of the first red host 442a can be greater than the contents of the second red host 444a. For example, the first red host 442a and the second red host 444a in the first layer 440A can be mixed, but is not limited to, with a weight ratio of about 7:3 to about 5.5:4.5. In some embodiments, the first red host 442a and the second red host 444a in the first layer 440A have a weight ratio of about 7:3, about 6:4, about 5.5, or about 4.5.

The second layer 440B can further include the second yellow-green host 444b. The second yellow-green host 444b can be an N-type or bipolar yellow-green host with relatively strong electron affinity property compared to the first yellow-green host 442b. For example, the second yellow-green host 444b can include, but is not limited to, an azine-containing organic compound.

In one embodiment, the second yellow-green host 444b can include, but is not limited to, Bis[2-(diphenylphosphino)phenyl]ether oxide (DPEPO), 1,3,5-Tri[(3-pyridyl)-phen-3-yl]benzene (TmPyPB), 2,6-Di(9H-carbazol-9-yl)pyridine (PYD-2Cz), Diphenyl-4-triphenylsilyl-phenylphosphine oxide (TSPO1), and/or combinations thereof.

In another embodiment, the second yellow-green host 444b can include electron transporting material and hole blocking material described below.

The yellow-green emitter 446b can include at least one of a yellow-green phosphorescent material, a yellow-green fluorescent material and a yellow-green delayed fluorescent material. For example, the yellow-green emitter 446b can include, but is not limited to, 5,6,11,12-Tetraphenylnaphthalene (Rubrene), 2,8-Di-tert-butyl-5,11-bis(4-tert-butylphenyl)-6,12-diphenyltetracene (TBRb), Bis(2-phenylbenzothiazolato)(acetylacetonate)iridium(III) (Ir(BT)₂(acac)) Bis(2-(9,9-diethytl-fluoren-2-yl)-1-phenyl-1H-benzo[d]imdiazolato)(acetylacetonate)iridium(II) (Ir(fbi)₂(acac)), Bis(2-phenylpyridine)(3-(pyridine-2-yl)-2H-chromen-2-onate)iridium(III) (fac-Ir(ppy)₂Pc), Bis(2-(2,4-difluorophenyl)quinolinexpicolinate)iridium(11l) (FPQIrpic), Bis(4-phenylthieno[3,2-c]pyridinato-N,C2′) (acetylacetonate) iridium(III) (PO-01), and/or combinations thereof.

As an example, the contents of the yellow-green host including the first yellow-green host 442b and the second yellow-green host 444b in the second layer 440B can be about 50 wt. % to about 99 wt. %, for example, about 80 wt. % to about 95 wt. %, and the contents of the yellow-green emitter 446b in the second layer 440B can be about 1 wt. % to about 50 wt. %, for example, about 5 wt. % to about 20 wt. %, but is not limited thereto. When the second layer 440B includes both the first yellow-green host 442b and the second yellow-green host 444b, the contents of the first yellow-green host 442b can be equal to or greater than the contents of the second yellow-green host 444b. For example, the first yellow-green host 442b and the second yellow-green host 444b in the second layer 440B can be mixed, but is not limited to, with a weight ratio of about 6:4 to about 5:5. In some aspects, the first yellow-green host 442b and the second yellow-green host 444b in the second layer 440B have a weight ratio of about 6:4, about 5.5:4.5, or about 5:5.

The third layer 440C can further include the second green host 444c. The second green host 444c can be an N-type or biopolar green host with relatively strong electron affinity property compared to the first green host 442c. For example, the second green host 444c can include, but is not limited to, an azine-containing organic compound.

In one embodiment, the second green host 444c can include, but is not limited to, DPEPO, TmPyPB, PYD-2Cz, TSPO1 and/or combinations thereof. In another embodiment, the second green host 444c can include electron transporting material or hole blocking material described below.

The green emitter 446c can include at least one of green phosphorescent material, green fluorescent material and green delayed fluorescent material. For example, the green emitter 446c can include, but is not limited to, [Bis(2-phenylpyridine)](pyridyl-2-benzofuro[2,3-b]pyridine)iridium, Tris[2-phenylpyridine]iridium(III) (Ir(ppy)₃), fac-Tris(2-phenylpyridine)iridium(III) (fac-Ir(ppy)₃), Bis(2-phenylpyridinexacetylacetonate)iridium(Ill) (Ir(ppy)₂(acac)), Tris[2-(p-tolyl)pyridine]iridium(III) (Ir(mppy)₃), Bis(2-(naphthalene-2-yl)pyridine)(acetylacetonate)iridium(III) (Ir(npy)₂acac), Tris(2-phenyl-3-methyl-pyridine)iridium (Ir(3mppy)₃), fac-Tris(2-(3-p-xylyl)phenyl)pyridine iridium(III) (TEG) and/or combinations thereof.

As an example, the contents of the green host including the first green host 442c and the second green host 444c in the third layer 440C can be about 50 wt. % to about 99 wt. %, for example, about 80 wt. % to about 95 wt. %, and the contents of the green emitter 446c in the third layer 440C can be about 1 wt. % to about 50 wt. %, for example, about 5 wt. % to about 20 wt. %, but is not limited thereto. When the third layer 440C includes both the first green host 442c and the second green host 444c, the contents of the first green host 442c can be greater than the contents of the second green host 444c. For example, the first green host 442c and the second green host 444c in the third layer 440C can be mixed, but is not limited to, with a weight ratio of about 6:4 to about 8:2. In some aspects, the first green host 442c and the second green host 444c in the third layer 440C have a weight ratio of about 6:4, about 6.5:3.5, about 7:3, about 7.5:2.5, or about 8:2.

The EML1 340 can be a blue emitting material layer. The EML1 340 can be a blue EML, a sky-blue EML or a deep-blue EML. The EML 1 340 can include a blue host and a blue emitter (blue dopant).

The blue host can include at least one of a P-type blue host and an N-type blue host. For example, the blue host can include, but is not limited to, mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole(CzBPCb), Bis(2-methylphenyl)diphenylsilane (UGH-1), 1,4-Bis(triphenylsilyl)benzene (UGH-2), 1,3-Bis(triphenylsilyl)benzene (UGH-3), 9,9-Spiorobifluoren-2-yl-diphenyl-phosphine oxide (SPPO1), 9,9′-(5-(Triphenylsilyl)-1,3-phenylene)bis(9H-carbazole)(SimCP) and/or combinations thereof.

The blue emitter can include at least one of blue phosphorescent material, blue fluorescent material and blue delayed fluorescent material. As an example, the blue emitter can include a pyrene-containing compound, an anthracene-containing compound and/or a boron-containing compound. For example, the blue emitter can include, but is not limited to, perylene, 4,4′-Bis[4-(di-p-tolylamino)styryl]biphenyl (DPAVBi), 4-(Di-p-tolylamino)-4-4′-[(di-p-tolylamino)styryl]stilbene (DPAVB), 4,4′-Bis[4-(diphenylamino)styryl]biphenyl (BDAVBi), 2,7-Bis(4-diphenylamino)styryl)-9,9-spirofluorene (spiro-DPVBi), [1,4-bis[2-[4-[N,N-di(p-tolyl)amino]phenyl]vinyl]benzene (DSB), 1-4-di-[4-(N,N-diphenyl)amino]styryl-benzene (DSA), 2,5,8,11-Tetra-tert-butylperylene (TBPe), Bis((2-hydroxylphenyl)-pyridine)beryllium (Bepp2), 9-(9-Phenylcarbazol-3-yl)-10-(naphthalen-1-yl)anthracene (PCAN), mer-Tris(1-phenyl-3-methylimidazolin-2-ylidene-C,C(2))′iridium(III) (mer-Ir(pmi)₃), fac-Tris(1,3-diphenyl-benzimidazolin-2-ylidene-C,C(2))′iridium(III) (fac-Ir(dpbic)₃), Bis(3,4,5-trifluoro-2-(2-pyridyl)phenyl-(2-carboxypyridyl))iridium(III) (Ir(tfpd)₂pic), tris(2-(4,6-difluorophenyl)pyridine)iridium(III) (Ir(Fppy)₃), Bis[2-(4,6-difluorophenyl)pyridinato-C²,N](picolinato)iridium(III)(FIrpic), 9,10-di(naphthalen-2-yl)anthracene (ADN), 2-methyl-9,10-bis(naphthalen-2-yl)anthracene (MADN), 2-tert-Butyl-9,10-di(naphthen-2-yl)anthracene (TBADN), 9,10-di(naphthalen-2-yl)-2-phenylanthracene (PADN), 9-phenyl-10-(p-tolyl)anthracene (PTA), 9-(1-naphthyl)-10-(p-tolyl)anthracene (1-NTA), 9-(2-naphthyl)-10-(p-tolyl)anthracene (2-NTA), 2-(3-(10-phenylanthracen-9-yl)-phenyl)dibenzo[b,d]furan (m-PPDF), 2-(4-(10-phenylanthracen-9-yl)phenyl)dibenzo[b,d]furan (p-PPDF), DABNA-1, DABNA-2, t-DABNA, v-DABNA and/or combinations thereof.

As an example, the contents of the blue host in the EML1 340 can be in a range between about 50 wt. % and about 99 wt. %, for example, about 80 wt. % and about 95 wt. %, and the contents of the blue emitter in the EML1 340 can be in a range between about 1 wt. % and about 50 wt. %, for example, about 5 wt. % and about 20 wt. %, but is not limited thereto. When the EML1 340 includes both the P-type blue host and the N-type blue host, the P-type blue host and the N-type blue host can be mixed, but is not limited to, with a weight ratio between about 4:1 to about 1:4, for example, about 3:1 to 1:3, about 2.5:1.5 or 1:1.

The HIL 310 is disposed between the first electrode 210 and the HTL1 320 and can improve an interface property between the inorganic first electrode 210 and the organic HTL1 320. In one embodiment, hole injecting material in the HIL 310 can include, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), TCTA, N,N′-Diphenyl-N,N′-bis(1-naphthyl)-1,1′-biphenyl-4,4″-diamine (NPB; NPD), N,N′-Bis{4-[bis(3-methylphenyl)amino]phenyl}-N,N′-diphenyl-4,4′-biphenyldiamine (DNTPD), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 2,3,5,6-Tetrafluoro-7,7,8,8-tetracyano-quinodimethane (F4-TCNQ), 1,3,4,5,7,8-hexafluoro-tetracyano-naphthoquinodimethane (F6-TCNNQ), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB), Di-[4-(N,N-di-p-tolyl-amino)-phenvl]cyclohexane (TAPC), N4,N4,N4′,N4′-Tetra[(1,1′-biphenyl)-4-yl]-(1,1′-biphenyl)-4,4′-diamine (BPBPA), the organic compound of the following Chemical Formula 8 and/or combinations thereof.

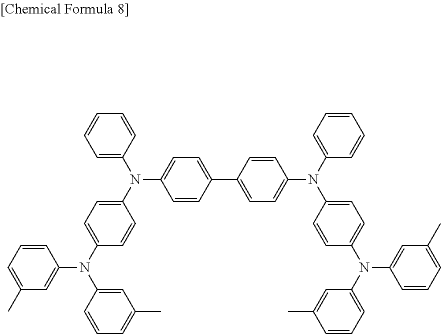 [SMILES: Cc1cccc(N(c2ccc(N(c3ccccc3)c3ccc(-c4ccc(N(c5ccccc5)c5ccc(N(c6cccc(C)c6)c6cccc(C)c6)cc5)cc4)cc3)cc2)c2cccc(C)c2)c1]

In another embodiment, the HIL 310 can include hole transporting material described below doped with the above hole injecting material (e.g., organic material such as HAT-CN, F4-TCNA and/or F6-TCNNQ). In this case, the contents of the hole injecting material in the HIL 310 can be, but is not limited to, about 2 wt. % to about 15 wt. %. In certain embodiments, the HIL 310 can be omitted in compliance of the OLED D1 property.

Each of the HTL 1 320 and the HTL2 420 transports holes to the EML 1 340 and the EML2 440, respectively. In one embodiment, the hole transporting material in the HTL1 320 and the HTL2 420 can independently include, but is not limited to, N,N′-Diphenyl-N,N′-bis(3-methylphenyl)-1,1′-biphenyl-4,4′-diamine (TPD), NPB(NPD), CBP, DNTPD, BPBPA, NPNPB, Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), TAPC, 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine, the organic compound of Chemical Formula 7 and/or combinations thereof.

Each of the ETL1 360 and the ETL2 460 transports electrons to the EML1 340 and the EML2 440, respectively. An electron transporting material included in the ETL1 360 and the ETL2 460 has high electron mobility so as to provide electrons stably with the EML1 340 and the EML2 440 by fast electron transportation.

In one embodiment, the electron transporting material in the ETL1 360 and the ETL2 460 can independently include at least one of an oxadiazole-containing compound, a triazole-containing compound, a phenanthroline-containing compound, a benzoxazole-containing compound, a benzothiazole-containing compound, a benzimidazole-containing compound, and a triazine-containing compound.

For example, the electron transporting material in the ETL1 360 and the ETL2 460 can independently include, but is not limited to, tris-(8-hydroxyquinoline) aluminum (Alq₃), 2-biphenyl-4-yl-5-(4-t-butylphenyl)-1,3,4-oxadiazole (PBD), spiro-PBD, lithium quinolate (Liq), 2,2′, 2″-(1,3,5-benzenetriyl)-tris(1-phenyl-1-H-benzimidazole) (TPBi), Bis(2-methyl-8-quinolinolato-N1,O8)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenathroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] dibromide (PFNBr), tris(phenylquinoxaline) (TPQ), Diphenyl-4-triphenylsilyl-phenylphosphine (TSPO1), 2-[4-(9,10-Di-2-naphthalen2-yl-2-anthracen-2-yl)phenyl]-1-phenyl-1H-benzimidazole (ZADN), and/or combinations thereof.

The EIL 470 is disposed between the second electrode 220 and the ETL2 460, and can improve physical properties of the second electrode 220 and therefore, can enhance the lifespan of the OLED D1. In one embodiment, electron injecting material in the EIL 470 can include, but is not limited to, an alkali metal halide and/or an alkaline earth metal halide such as LiF, CsF, NaF, BaF₂ and the like, and/or an organometallic Compound such as Liq, lithium benzoate, sodium stearate, and the like. In certain embodiments, the EIL 470 can be omitted.

In another embodiment, the ETL2 460 and the EIL 470 can have a single layered structure. In this case, the above electron transporting material and/or the electron injecting material can be mixed with each other. As an example, the ETL2 460/EIL 470 can include two or more different electron transporting materials. For example, two electron transporting materials in the ETL/EIL are mixed with a weight ratio of about 3:7 to about 7:3, but is not limited thereto. In some aspects, the ETL/EIL are mixed with a weight ratio of about 3.5:6.5, about 4:6, about 1:1, or about 6.5:3.5.

When holes are transferred to CGL 380 or the second electrode 220 via the EML 1 340 and the EML2 440 and/or electrons are transferred to CGL 380 or the first electrode 210 via the EML1 340 and the EML2 440, the OLED D1 can have short lifespan and reduced luminous efficiency. In order to prevent those phenomena, the OLED D1 can have at least one exciton blocking layer adjacent to the EML1 340 and/or the EML2 440.

As an example, the OLED D1 can include a first electron blocking layer (EBL1) 330 disposed between the HTL1 320 and the EML 1 340 and/or a second electron blocking layer (EBL2) 430 disposed between the HTL2 420 and the EML2 440, so as to control and prevent electron transfers. In one example embodiment, electron blocking material in the EBL1 330 and the EBL2 430 can independently include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof.

In addition, the OLED D1 can further include a first hole blocking layer (HBL1) 350 disposed between the EML1 340 and the ETL1 360 and/or a second hole blocking layer (HBL2) 450 disposed between the EML2 440 and the ETL2 460 so that holes cannot be transferred from the EML1 340 and/or the EML2 440 to the ETL1 360 and/or the ETL2 460. In one example embodiment, the hole blocking material in the HBL1 350 and the HBL2 450 can independently include, but is not limited to, at least one of oxadiazole-containing compounds, triazole-containing compounds, phenanthroline-containing compounds, benzoxazole-containing compounds, benzothiazole-containing compounds, benzimidazole-containing compounds, and triazine-containing compounds.

For example, hole blocking material in the HBL1 350 and the HBL2 450 can independently include material having a relatively low HOMO (highest occupied molecular orbital) energy level compared to the luminescent materials in EML1 340 and the EML2 440. In one embodiment, the hole blocking material in the HBL1 350 and the HBL2 450 can independently include, but is not limited to, BCP, BAlq, Alq₃, PBD, spiro-PBD, Liq, Bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole, TSPO1 and/or combinations thereof. In certain embodiments, the EBL1 330, the EBL2 430, the HBL1 350 and/or the HBL2 450 can be omitted.

The CGL 380 includes an N-type charge generation layer (N-CGL) 385 disposed between the ETL1 360 and the HTL2 420 and a P-type charge generation layer (P-CGL) 390 disposed between the N-CGL 385 and the HTL2 420. The N-CGL 385 provides electrons to the EML 1 340 in the first emitting part 300. The P-CGL 390 provides holes to the EML2 440 in the second emitting part 400.

The N-CGL 385 can be an organic layer including electron transporting material doped with an alkali metal such as Li, Na, K and Cs and/or an alkaline earth metal such as Mg, Sr, Ba and Ra. For example, the contents of the alkali metal and/or the alkaline earth metal in the N-CGL 385 can be, but is not limited to, between about 0.1 wt. % and about 30 wt. %, for example, about 1 wt. % and about 10 wt. %.

In one embodiment, the P-CGL 390 can include, but is not limited to, inorganic material selected from the group consisting of WOₓ, MoOₓ, Be₂O₃, V₂O₅ and/or combinations thereof. In another embodiment, the P-CGL 390 can include organic material of the hole transporting material doped with the hole injecting material (e.g., organic material such as HAT-CN, F4-TCNQ and/or F6-TCNNQ). In this case, the contents of the hole injecting material in the P-CGL 390 can be, but is not limited to, between about 2 wt. % and about 15 wt. %.

Each of the first layer 440A of the red emitting material layer, the second layer 440B of the yellow-green emitting material layer and the third layer 440C of the green emitting material layer includes at least one host with controlled charge mobility, and thus, the emission area can be distributed uniformly in the entire EML2 440. It is possible to prevent degradations of the luminous materials and charge transporting materials caused by interactions with the concentrated excitons at a specific area and/or the non-radiative quenching excitons. The luminous lifespan of the OLED D1 can be improved significantly with maintaining luminous efficiency. In certain embodiment, the emissive layer 230 can consist of the second emitting part 400 without the first emitting part 300.

An OLED can have three or more emitting parts to form a tandem structure. FIG. 6 is a schematic cross-sectional view illustrating an organic light emitting diode in accordance with yet another example embodiment of the present disclosure.

As illustrated in FIG. 6, the OLED D2 includes first and second electrodes 210 and 220 facing each other and an emissive layer 230A disposed between the first electrode 210 and the second electrode 220. The emissive layer 230A includes a first emitting part 300 disposed between the first electrode 210 and the second electrode 220, a second emitting part 400A disposed between the first emitting part 300 and the second electrode 220, a third emitting part 500 disposed between the second emitting part 400A and the second electrode 220, a first charge generation layer (CGL1) 380 disposed between the first emitting part 300 and the second emitting part 400A, and a second charge generation layer (CGL2) 480 disposed between the second emitting part 400A and the third emitting part 500.

The first emitting part 300 includes a first EML (EML1) 340. The first emitting part 300 can further include at least one of a first hole transport layer (HTL1) 320 disposed between the first electrode 210 and the EML1 340 and a first electron transport layer (ETL1) 360 disposed between the EML1 340 and the CGL1 380. The first emitting part 300 can further include a hole injection layer (HIL) 310 disposed between the first electrode 210 and the HTL 1 320. Alternatively, or additionally, the first emitting part 300 can further include a first electron blocking layer (EBL1) 330 disposed between the HTL1 320 and the EML1 340 and/or a first hole blocking layer (HBL1) 350 disposed between the EML1 340 and the ETL1 360.

The second emitting part 400A includes a second EML (EML2) 440. The second emitting part 400A can further include at least one of a second hole transport layer (HTL2) 420 disposed between the CGL1 380 and the EML2 440 and a second electron transport layer (ETL2) 460 disposed between the EML2 440 and the CGL2 480. Alternatively, or additionally, the second emitting part 400A can further include a second electron blocking layer (EBL2) 430 disposed between the HTL2 420 and the EML2 440 and/or a second hole blocking layer (HBL2) 450 disposed between the EML2 440 and the ETL2 460.

The third emitting part 500 includes a third EML (EML3) 540. The third emitting part 500 can further include at least one of a third hole transport layer (HTL3) 520 disposed between the CGL2 480 and the EML3 540 and a third electron transport layer (ETL3) 560 disposed between the EML3 540 and the second electrode 220. The third emitting part 500 can further include an electron injection layer (EIL) 570 disposed between the ETL3 560 and the second electrode 220. Alternatively, or additionally, the third emitting part 500 can further include a third electron blocking layer (EBL3) 530 disposed between the HTL3 520 and the EML3 540 and/or a third hole blocking layer (HBL3) 550 disposed between the EML3 540 and the ETL3 560.

The CGL 1 380 is disposed between the first emitting part 300 and the second emitting part 400A and the CGL2 480 is disposed between the second emitting part 400A and the third emitting part 500. The CGL1 380 includes a first N-type charge generation layer (N-CGL1) 385 disposed between the ETL1 360 and the HTL2 420 and a first P-type charge generation layer (P-CGL 1) 390 disposed between the N-CGL1 385 and the HTL2 420. The CGL2 480 includes a second N-type charge generation layer (N-CGL2) 485 disposed between the ETL2 460 and the HTL3 520 and a second P-type charge generation layer (P-CGL2) 490 disposed between the N-CGL2 485 and the HTL3 520.

Each of the N-CGL1 385 and the N-CGL2 485 injects electrons to the EML1 340 of the first emitting part 300 and the EML2 440 of the second emitting part 400A, respectively, and each of the P-CGL 1 390 and the P-CGL2 490 injects holes to the EML2 440 of the second emitting part 400A and the EML3 540 of the third emitting part 500, respectively.

The materials included in the HIL 310, the HTL1 to the HTL3 320,420 and 520, the EBL1 to the EBL3 330, 430 and 530, the HBL1 to the HBL3 350, 450 and 550, the ETL1 to the ETL3 360, 460 and 560, the EIL 570, the CGL 1 380, and the CGL2 480 can be identical to the materials with referring to FIG. 3. In certain embodiment, the HIL 310, the EBL1 to the EBL3 330, 430 and 530, the HBL1 to the HBL3 350, 450 and 550 and/or the EIL 570 can be omitted.

At least one, for example, one or two, of the EML1 340, the EML2 440 and the EML3 540 can emit red, yellow-green and green color lights, and the rest of the EML1 340, the EML2 440 and the EML3 540 can emit blue color light so that the OLED D2 can realize white (W) emission. Hereinafter, the OLED where the EML2 440 emits red, yellow-green and green color lights and each of the EML 1 340 and the EML3 540 emits blue color light will be described in detail.

The EML1 340 and the EML3 540 can be a first blue emitting material layer and a second blue emitting material layer, respectively. In this case, each of the EML1 340 and the EML3 540 can be independently a blue EML, a sky-blue EML or a deep-blue EML. Each of the EML1 340 and the EML3 540 can independently include a blue host and a blue emitter.

Each of the blue host and the blue emitter can be identical to the blue host and the blue dopant with referring to FIG. 3. For example, the blue emitter can include at least one of blue phosphorescent material, blue fluorescent material and blue delayed fluorescent material. Alternatively, the blue host and/or the blue emitter in the EML 1 340 can be identical to or different from the blue host and/or the blue emitter in the EML3 540 in terms of color and/or luminous efficiency.

As an example, the contents of the blue host in the EML1 340 and the EML3 540 can be in a range between about 50 wt. % and about 99 wt. %, for example, about 80 wt. % and about 95 wt. %, and the contents of the blue emitter in the EML1 340 and the EML3 540 can be in a range between about 1 wt. % and about 50 wt. %, for example, about 5 wt. % and about 20 wt. %, but is not limited thereto. When the EML1 340 and/or the EML3 540 include both the P-type blue host and the N-type blue host, the P-type blue host and the N-type blue host can be mixed, but is not limited to, with a weight ratio between about 4:1 to about 1:4, for example, about 3:1 to 1:3.

The EML2 440 can include a red emitting material layer (R-EML, first layer) 440A, a yellow-green emitting material layer (YG-EML, second layer) 440B and a green emitting material layer (G-EML, third layer) 440C disposed sequentially between the CGL1 380 and the CGL2 480, for example, between the HTL2 420 or the EBL2 430 and the ETL2 460 or the HBL2 450.

The first layer 440A includes a first red host 442a, a red emitter (red dopant) 446a, and optionally, a second red host 444a. The second layer 440B includes a first yellow-green host 442b, a yellow-green emitter (yellow-green dopant) 446b, and optionally, a second yellow-green host 444b. The third layer 440C includes a first green host 442c, a green emitter (green dopant) 446c, and optionally, a second green host 444c.

The materials and contents of the first red host 442a, the second red host 444a, the red emitter 446a, the first yellow-green host 442b, the second yellow-green host 444b, the yellow-green emitter 446b, the first green host 442c, the second green host 444c and the green emitter 446c and the thicknesses of the first layer 440A, the second layer 440B and the third layer 440C can be identical to the corresponding materials, contents and the thickness with referring to FIGS. 3 and 5.

At least one emitting part of the OLED D2 with a tandem structure includes the first layer 440A of the red emitting material layer, the second layer 440B of the yellow-green emitting material layer and the third layer 440C of the green emitting material layer. Each of the first to third layers 440A, 440B and 440C includes a host with controlled charge mobility, and thus, the emission area can be distributed uniformly in the entire EML2 440. It is possible to prevent degradations of the luminous materials in the EML2 440 and charge transporting materials in the HTL2 420 and/or the ETL2 460 caused by interactions with the concentrated excitons at a specific area and/or the non-radiative quenching excitons. The luminous lifespan of the OLED D2 can be improved significantly with maintaining luminous efficiency.

### EXAMPLES

The following examples are not intended to be limiting. The above disclosure provides many different embodiments for implementing the features of the invention, and the following examples describe certain embodiments. It will be appreciated that other modifications and methods known to one of ordinary skill in the art can also be applied to the following experimental procedures, without departing from the scope of the invention.

### Example 1 (Ex. 1): Fabrication of OLED

An organic light emitting diode that includes a red emitting material layer, a yellow-green emitting material layer and a green emitting material layer each of which includes a host with controlled charge mobility. A glass substrate onto which ITO (1200 Å) was coated as a thin film was washed and ultrasonically cleaned by solvent such as isopropyl alcohol, acetone and dried at 100° C. oven. The substrate was transferred to a vacuum chamber for depositing emissive layer, and then the emissive layer and a cathode were deposited as the following order:

Hole injection layer (HIL below, 100 Å); hole transport layer (HTL below, 80 Å); red emitting material layer (host (RHH below: Compound 1-1 in Chemical Formula 2=4:6 by weight ratio, 98 wt. %), RD below (Ir(piq)₂(acac), 2 wt. %), 150 Å); yellow-green emitting material layer (host (EH (TPBi) below: Compound 2 in Chemical Formula 4=5:5 by weight ratio, 80 wt. %), YGD below (Ir(BT)₂(acac), 20 wt. %), 100 Å); green emitting material layer (host (EH below: Compound 3 in Chemical Formula 6=7:3 by weight ratio, 93 wt. %), GD below (Ir(ppy)₃, 7 wt. %), 300 Å); electron transport layer (ETL (TPBi), 200 Å); electron injection layer (EIL below (Bphen), 220 Å); and cathode (Al).

The fabricated OLED was encapsulated with glass and then transferred from the deposition chamber to a dry box in order to form a film. Then, the OLED was encapsulated with UV-cured epoxy resin and water getter. The structures of materials of hole injecting material, hole transporting material, luminous host, red dopant, yellow-green dopant, green dopant, electron transporting material and electron injecting material are illustrated in the following:

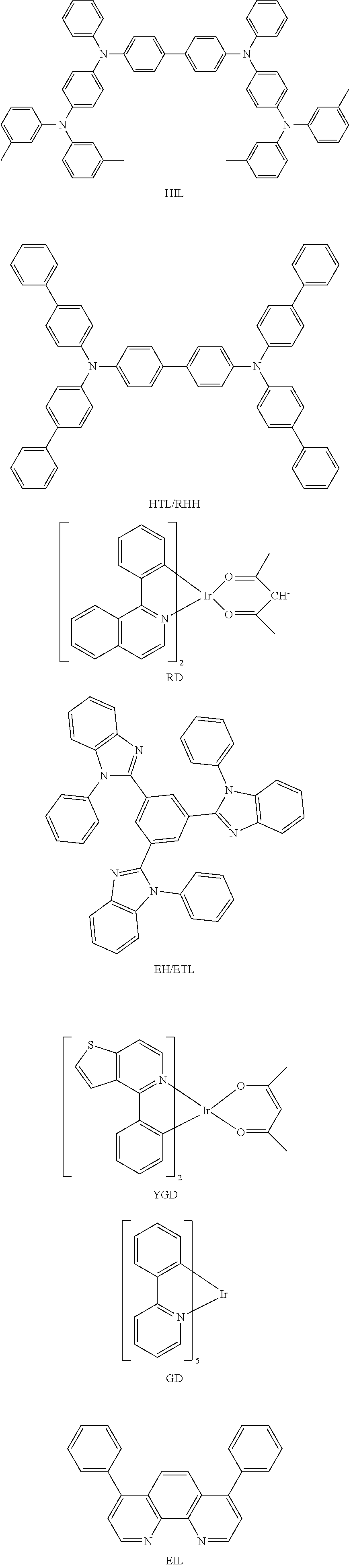

### Examples 2-3 (Ex.2-3): Fabrication of OLED

An OLED was fabricated using the same structure as Example 1, except that Compound 1-3 in Chemical Formula 2 (Ex. 2) and Compound 1-4 in Chemical Formula 2 (Ex. 3) instead of Compound 1-1 was used as the N-type host in the red emitting material layer.

### Comparative Example 1 (Ref. 1): Fabrication of OLED

An OLED was fabricated using the same structure as Example 1, except that Compound Ref. 1 below instead of Compound 1-1 as the N-type host in the red emitting material layer, Compound Ref. 2 below instead of Compound 2 as the P-type host in the yellow-green emitting material layer and Compound Ref. 3 instead of Compound 3 as the P-type host in the green emitting material layer were used.

### Comparative Example 2 (Ref. 2): Fabrication of OLED

An OLED was fabricated using the same structure as Comparative Example 1, except that Compound 3 in Chemical Formula 6 instead of the Compound Ref. 2 below was used as the P-type host in the yellow-green emitting material layer.

### Comparative Example 3 (Ref. 3): Fabrication of OLED

An OLED was fabricated using the same structure as Comparative Example 1, except that Compound 2 in Chemical Formula 4 instead of the Compound Ref. 2 below was used as the P-type host in the yellow-green emitting material layer.

### Comparative Example 4 (Ref. 4): Fabrication of OLED

An OLED was fabricated using the same structure as Comparative Example 1, except that Compound 3 in Chemical Formula 6 instead of the Compound Ref. 3 below was used as the P-type host in the green emitting material layer.

### Comparative Example 5 (Ref. 5): Fabrication of OLED

An OLED was fabricated using the same structure as Comparative Example 1, except that Compound 2 in Chemical Formula 4 instead of the Compound Ref. 2 below as the P-type host in the yellow-green emitting material layer and Compound 3 in Chemical Formula 6 instead of the Compound Ref. 3 below as the P-type host in the green emitting material layer were used.

### Comparative Examples 6-7 (Ref. 6-7): Fabrication of OLED

An OLED was fabricated using the same structure as Comparative Example 1, except that Compound 1-1 (Ref. 6) and Compound 1-2 (Ref. 7) in Chemical Formula 2 instead of the Compound Ref. 1 below were used as the N-type host in the red emitting material layer.

### [Reference Compound]

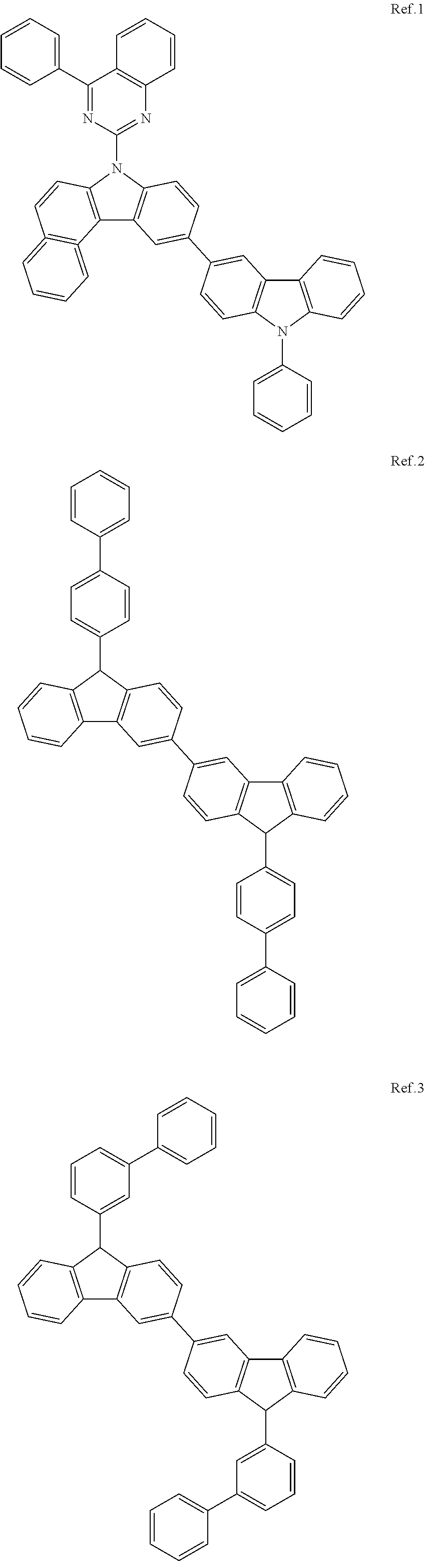

### Example 4 (Ex.4): Fabrication of EOD

An electron only device (EOD) where EIL, a red emitting material layer (RHH, Compound 1-1 and RD), ETL, EIL and Al (cathode) were disposed sequentially on the ITO. The materials in the electrodes, EIL, red emitting material layer and ET L were identical to the materials in Example 1.

### Examples 5-7 (Ex.5-7): Fabrication of EOD

An EOD was fabricated using the same structure as Example 4, except that Compound 1-2 (Ex. 5), Compound 1-3 (Ex. 6) and Compound 1-4 (Ex. 7) in Chemical Formula 2 instead of the Compound 1-1 were used as the N-type host in the red emitting material layer.

### Comparative Example 8 (Ref. 8): Fabrication of EOD

An EOD was fabricated using the same structure as Example 4, except that the Compound Ref. 1 instead of the Compound 1-1 were used as the N-type host in the red emitting material layer.

### Experimental Example 1: Measurement of Current Density and Electron Mobility

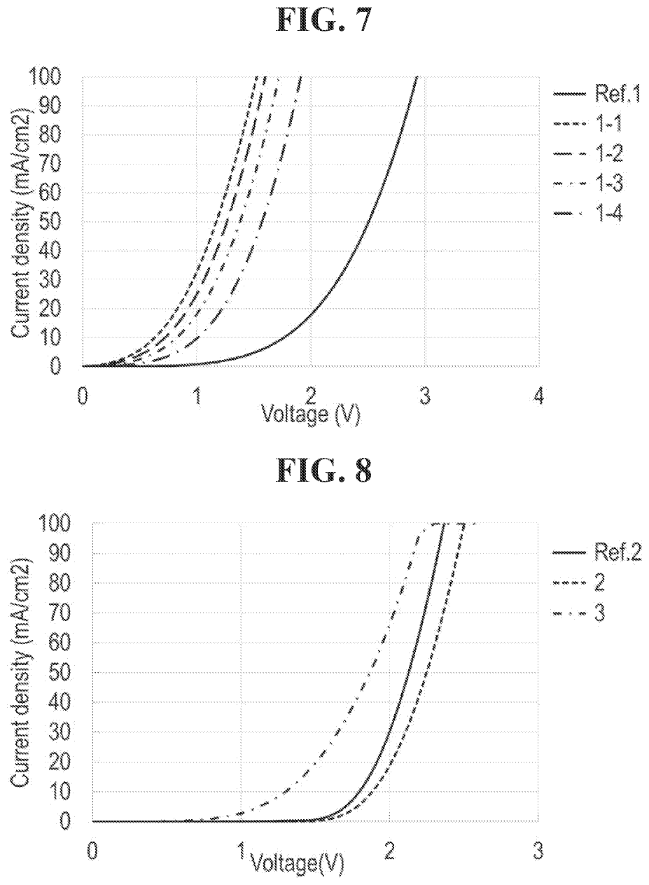

An electron only device fabricated in Examples 4 to 7 and Comparative Example 8 were connected to an external power source and then the current density and the electron mobility of the N-type host were measured using current source (KEITHLEY) and a photometer PR650 at room temperature. The measurement results for the current density are illustrated in FIG. 7. As illustrated in FIG. 7, compared to the electron only device fabricated in Comparative Example 8 that includes the Compound Ref. 1 as the N-type host in the red emitting material layer, in the electron only device fabricated in Examples 4 to 7 each of which includes the Compounds 1-1, 1-2, 1-3 and 1-4 as the N-type host in the red emitting material layer, the current density was improved. The electron mobility of the Compound Ref. 1 was 2.3E-05 cm²/V·S, the electron mobility of the Compound 1-1 was 2.2E-4 cm²/V·S, and the electron mobility of the Compounds 1-2, 1-3 and 1-4 was in a range between 1.0E-04 cm²/V·S and 1.0E-03 cm²/V·S.

### Example 8 (Ex.8): Fabrication of HOD

A hole only device (HOD) where HIL, HTL, yellow-green emitting material layer (EH, Compound 2, YGD), HTL and Al (cathode) were disposed sequentially on the ITO. The materials in the electrodes, HIL, HTL and the yellow-green emitting material layer were identical to the materials in Example 1.

### Comparative Examples 10-11 (Ref. 10-11): Fabrication of HOD

A HOD was fabricated using the same structure as Example 8, except that the Compound Ref. 2 (Ref. 10) and the Compound 3 (Ref. 11) in Chemical Formula 3 instead of the Compound 2 were used as the P-type host in the yellow-green emitting material layer.

### Experimental Example 2: Measurement of Current Density and Hole Mobility

Current density and hole mobility for the hole only device fabricated in Example 8 and Comparative Examples 10-11 were measured with the same process as Experimental Example 1. The measurement results for the current density are illustrated in FIG. 8. As illustrated in FIG. 8, compared to the hole only device fabricated in Comparative Example 10 that includes the Compound Ref. 2 as the P-type host in the yellow-green emitting material layer, in the hole only device fabricated in Example 8 that includes the Compound 2 as the P-type host in the yellow-green emitting material layer, the current density was reduced, but in the hole only device fabricated in Comparative Example 11 that includes the Compound 3 as the P-type host in the yellow-green emitting material layer, the current density was improved. The hole mobility of the Compound Ref. 2 was in a range between 1.0E-06 cm²/V·S and 4.0E-5 cm²/V·S (e.g., 1.0E-05 cm²/V·S), the hole mobility of the Compound 2 was in a range between 5.0E-08 cm²/V·S and 1.0E-05 cm²/V·S (e.g., 5.0E-06 cm²/V·S), and the hole mobility of the Compound 3 was in a range between 3.0E-05 cm²/V·S and 1.0E-4 cm²/V·S (e.g., 5.0E-05 cm²/V·S).

### Example 9 (Ex.9): Fabrication of HOD

A hole only device (HOD) where HIL, HTL, green emitting material layer (EH, Compound 3, GD), HTL and Al (cathode) were disposed sequentially on the ITO. The materials in the electrodes, HIL, HTL and the green emitting material layer were identical to the materials in Example 1.

### Comparative Example 12 (Ref. 12): Fabrication of HOD

A HOD was fabricated using the same structure as Example 9, except that the Compound Ref. 3 instead of the Compound 3 in Chemical Formula 6 was used as the P-type host in the green emitting material layer.

### Experimental Example 3: Measurement of Current Density and Hole Mobility

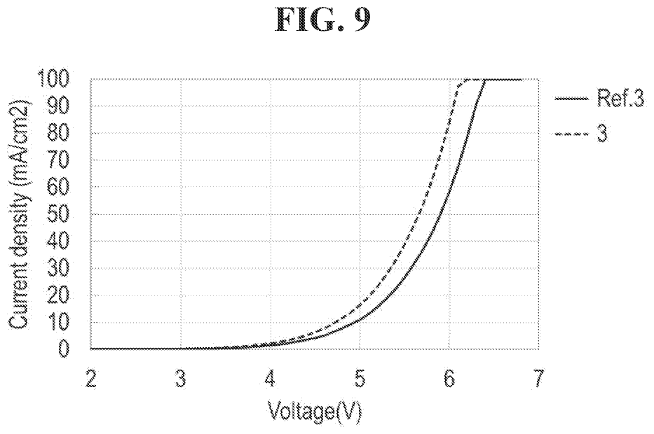

Current density and hole mobility for the hole only device fabricated in Example 9 and Comparative Example 12 were measured with the same process as Experimental Example 1. The measurement results for the current density are illustrated in FIG. 9. As illustrated in FIG. 9, compared to the hole only device fabricated in Comparative Example 12 that includes the Compound Ref. 3 as the P-type host in the green emitting material layer, in the hole only device fabricated in Example 9 that includes the Compound 3 as the P-type host in the green emitting material layer, the current density was improved. The hole mobility of the Compound 3 was in a range between 3.0E-05 cm²/V·S and 1.0E-4 cm²/V·S (e.g., 5.0E-05 cm²/V·S).

### Experimental Example 4: Measurement of Luminous Properties of OLED

Each of the OLEDs fabricated in Examples 1 to 3 and Comparative Examples 1 to 7 was connected to an external power source and then luminous properties for all the OLEDs were evaluated using a constant current source (KEITHLEY) and a photometer PR650 at room temperature. In particular, current efficiency (cd/A, relative value) of red and green lights, time period (T₉₅, relative value) at which the luminance was reduced to 95% from initial luminance of the red and green lights, and driving voltage (V, relative value) were measured at a current density of 10 mA/cm² and 100 mA/cm². The measurement results are indicated in the following Table 1.

TABLE 1
Luminous Properties of OLED

| | | R | G | R | G | | |
|---|---|---|---|---|---|---|---|
| Sample | Host* | (cd/A) | (cd/A) | T₉₅ | T₉₅ | V** | V*** |
| Ref. 1 | Ref. 1 + Ref. 2 + Ref. 3 | 100% | 100% | 100% | 100% | 0 | 0 |
| Ref. 2 | Ref. 1 + 3 + Ref. 3 | 98% | 101% | 91% | 96% | −0.02 | −0.02 |
| Ref. 3 | Ref. 1 + 2 + Ref. 3 | 98% | 100% | 142% | 121% | −0.07 | −0.08 |
| Ref. 4 | Ref. 1 + Ref. 2 + 3 | 97% | 102% | 116% | 105% | −0.01 | 0.03 |
| Ref. 5 | Ref. 1 + 2 + 3 | 99% | 104% | 143% | 112% | +0.12 | +0.13 |
| Ref. 6 | 1 − 1 + Ref. 2 + Ref. 3 | 92% | 97% | 124% | 113% | −0.1 | 0 |
| Ref. 7 | 1 − 2 + Ref. 2 + Ref. 3 | 99% | 99% | 122% | 125% | +0.2 | +0.23 |
| Ex. 1 | 1 − 1 + 2 + 3 | 97% | 98% | 236% | 133% | +0.1 | +0.07 |
| Ex. 2 | 1 − 3 + 2 + 3 | 100% | 97% | 237% | 133% | +0.14 | +0.12 |
| Ex. 3 | 1 − 4 + 2 + 3 | 99% | 96% | 222% | 128% | +0.11 | +0.15 |

*N-type red host + P-type yellow-green host + P-type green host
**10 mA/cm²
***100 mA/cm²

As indicated in Table 1, when the OLED includes the Compound 3 with beneficial hole mobility as the P-type yellow-green host as Comparative Example 2, the luminous lifespan was lowered considerably. In addition, when the OLED includes only one host or two hosts with controlled charge mobility in the red emitting material layer, the yellow-green emitting material layer and the green emitting material as Comparative Examples 3 to 7, the luminous lifespan was little improved. On the other hand, compared to the OLEDs fabricated in Comparative Examples 1 to 7, in the OLEDs fabricated in Examples 1 to 3, each of which includes hosts with controlled charge mobility in the red emitting material layer, the yellow-green emitting material layer and the green emitting material layer, the luminous lifespan of the red light and the green light was improved significantly with maintaining equivalent luminous efficiency.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. An organic light emitting diode, comprising:
a first electrode;
a second electrode facing the first electrode; and
an emissive layer disposed between the first electrode and the second electrode, and comprising at least one emitting part,
wherein the at least one emitting part comprises:
a red emitting material layer comprising a first red host;
a yellow-green emitting material layer disposed between the red emitting material layer and the second electrode, and comprising a first yellow-green host; and
a green emitting material layer disposed between the yellow-green emitting material layer and the second electrode, and comprising a first green host,
wherein the first red host has an electron mobility in a range between about 1E-04 cm²/V·S and about 1E-03 cm²/V·S,
wherein the first yellow-green host has a hole mobility in a range between about 5E-08 cm²/V·S and about 1E-05 cm²/V·S, and
wherein the first green host has a hole mobility in a range between about 3E-05 cm²/V·S and about 1E-4 cm²/V·S.

2. The organic light emitting diode of claim 1, wherein the first red host comprises an organic compound having the following structure of Chemical Formula 1: 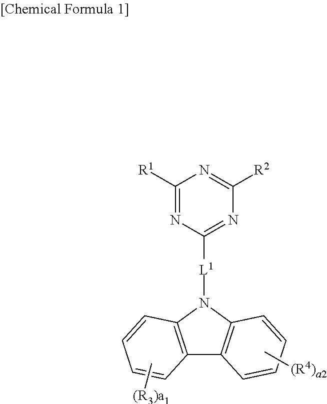
wherein, in Chemical Formula 1,
each of R¹ and R² is independently an unsubstituted or substituted C₆-C₃₀ aryl group or an unsubstituted or substituted C₃-C₃₀ hetero aryl group;
R³ is protium, deuterium or an unsubstituted or substituted C₁-C₂₀ alkyl group, where each R³ is identical to or different from each other when a1 is 2, 3 or 4;
R⁴ is each independently protium, deuterium or an unsubstituted or substituted C₁₂-C₃₀ hetero aryl group having a carbazolyl moiety, wherein one of R⁴s is the unsubstituted or substituted C₁₂-C₃₀ hetero aryl group having a carbazolyl moiety;
L¹ is an unsubstituted or substituted C₆-C₃₀ arylene group;
a1 is 0, 1, 2, 3 or 4; and
a2 is 0, 1, 2, 3 or 4.

3. The organic light emitting diode of claim 2, wherein in Chemical Formula 1:
each of R¹ and R² is independently a moiety selected from: substituted or unsubstituted phenyl, 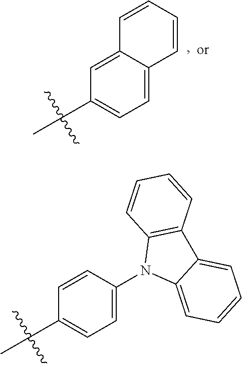 [SMILES: *c1ccc2ccccc2c1 ; *c1ccc(-n2c3ccccc3c3ccccc32)cc1]
R³ is protium or deuterium; and
R⁴ is

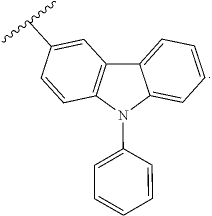 [SMILES: *c1ccc2c(c1)c1ccccc1n2-c1ccccc1]

4. The organic light emitting diode of claim 1, wherein the first red host comprises at least one of the following organic compounds:

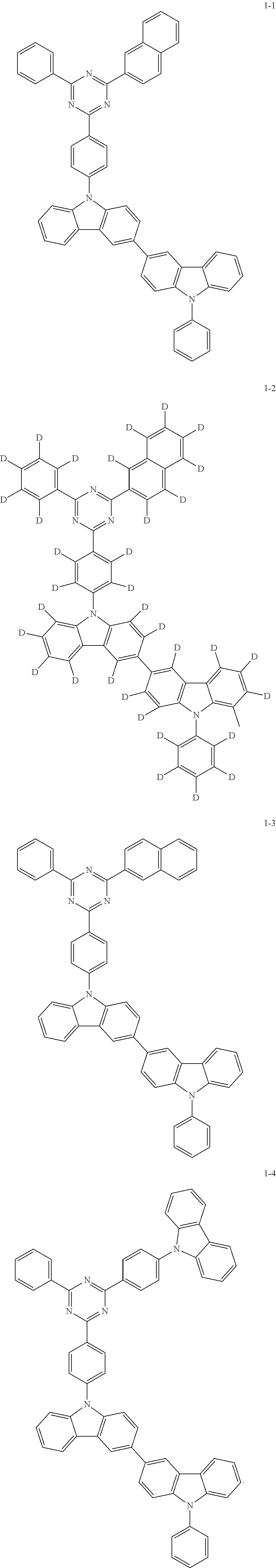

5. The organic light emitting diode of claim 1, wherein the first yellow-green host comprises an organic compound having the following structure of Chemical Formula 3: 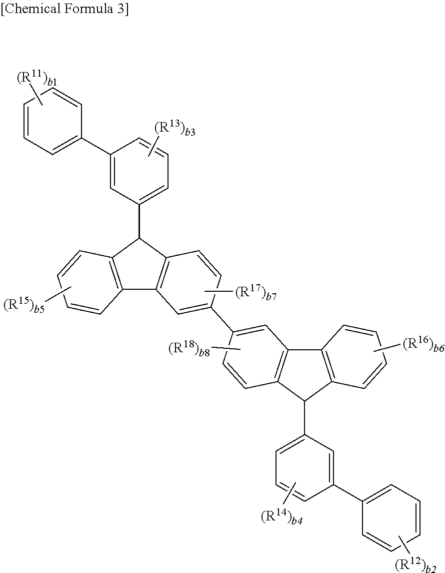
wherein, in Chemical Formula 3
each of R¹¹ to R¹⁸ is independently deuterium or an unsubstituted or substituted C₁-C₂₀ alkyl group, where at least one of R¹¹ to R¹⁸ is deuterium or a deuterium-substituted C₁-C₂₀ alkyl group, where each R¹¹ is identical to or different from each other when b1 is 2, 3, 4 or 5, where each R¹² is identical to or different from each other when b2 is 2, 3, 4 or 5, each R¹³ is identical to or different from each other when b3 is 2, 3 or 4, each R¹⁴ is identical to or different from each other when b4 is 2, 3 or 4, each R¹⁵ is identical to or different from each other when b5 is 2, 3 or 4, each R¹⁶ is identical to or different from each other when b6 is 2, 3 or 4, each R¹⁷ is identical to or different from each other when b7 is 2 or 3, and each R¹⁸ is identical to or different from each other when b8 is 2 or 3;
each of b1 and b2 is independently 0, 1, 2, 3, 4 or 5;
each of b3, b4, b5 and b6 is independently 0, 1, 2, 3 or 4; and
each of b7 and b8 is independently 0, 1, 2 or 3, where at least one of b1 to b8 is not 0.

6. The organic light emitting diode of claim 5, wherein, in Chemical Formula 3, each of R¹¹ to R¹⁸ is independently deuterium, methyl, ethyl, propyl, isopropyl, butyl, isobutyl, sec-butyl, pentyl, isopentyl, or sec-butyl.

7. The organic light emitting diode of claim 1, wherein the first green host comprises an organic compound having the following structure of Chemical Formula 5: 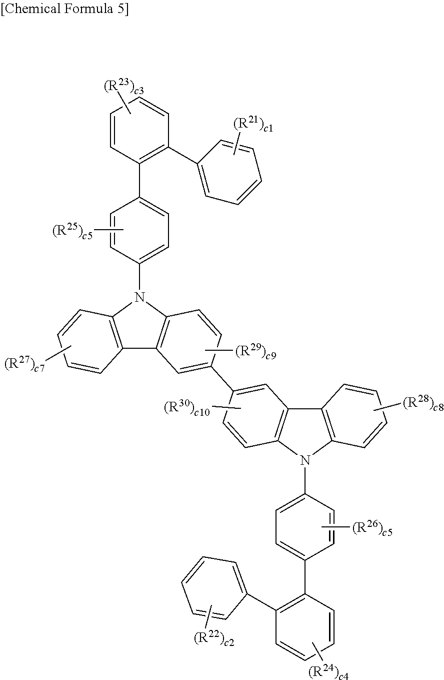
wherein, in Chemical Formula 5,
each of R²¹ to R³⁰ is independently deuterium or an unsubstituted or substituted C₁-C₂₀ alkyl group, where at least one of R²¹ to R³⁰ is deuterium or a deuterium-substituted C₁-C₂₀ alkyl group, where each R²¹ is identical to or different from each other when c1 is 2, 3, 4 or 5, where each R²² is identical to or different from each other when c2 is 2, 3, 4 or 5, each R²³ is identical to or different from each other when c3 is 2, 3 or 4, each R²⁴ is identical to or different from each other when c4 is 2, 3 or 4, each R²⁵ is identical to or different from each other when c5 is 2, 3 or 4, each R²⁶ is identical to or different from each other when c6 is 2, 3 or 4, each R^{2′} is identical to or different from each other when c7 is 2, 3 or 4, each R²¹ is identical to or different from each other when c8 is 2, 3 or 4, each R²⁹ is identical to or different from each other when c9 is 2 or 3, and each R³⁰ is identical to or different from each other when c10 is 2 or 3;
each of c1 and c2 is independently 0, 1, 2, 3, 4 or 5;
each of c3, c4, c5, c6, c7 and c8 is independently 0, 1, 2, 3 or 4; and
each of c9 and c10 is independently 0, 1, 2 or 3, where at least one of c1 to c10 is not 0.

8. The organic light emitting diode of claim 7, wherein in Chemical Formula 5, each of R²¹ to R³⁰ is independently deuterium, methyl, ethyl, propyl, iso-propyl, butyl, iso-butyl, sec-butyl, pentyl, iso-pentyl, or sec-pentyl.

9. The organic light emitting diode of claim 1, wherein the red emitting material layer further comprises a second red host, and wherein the first red host and the second red host in the red emitting material layer are mixed with a weight ratio in a range between about 7:3 and about 5.5; 4.5; or
wherein the yellow-green emitting material layer further comprises a second yellow-green host, and wherein the first yellow-green host and the second yellow-green host in the yellow-green emitting material layer are mixed with a weight ratio in a range between about 6:4 and about 5:5; or
wherein the green emitting material layer further comprises a second green host, and wherein the first green host and the second green host in the green emitting material layer are mixed with a weight ratio in a range between about 6:4 and about 8:2.

10. The organic light emitting diode of claim 1, wherein the red emitting material layer has a thickness greater than a thickness of the yellow-green emitting material layer; or
wherein the green emitting material layer has a thickness equal to or greater than a thickness of the red emitting material layer.

11. The organic light emitting diode of claim 1, wherein the emissive layer comprises:
a first emitting part;
a second emitting part disposed between the first emitting part and the second electrode; and
a first charge generation layer disposed between the first emitting part and the second emitting part, and
wherein one of the first emitting part and the second emitting part comprises the red emitting material layer, the yellow-green emitting material layer and the green emitting material layer.

12. The organic light emitting diode of claim 11, wherein the emissive layer further comprises:
a third emitting part disposed between the second emitting part and the second electrode; and
a second charge generation layer disposed between the second emitting part and the third emitting part.

13. An organic light emitting diode, comprising:
a first electrode;
a second electrode facing the first electrode; and
an emissive layer disposed between the first electrode and the second electrode,
wherein the emissive layer comprises:
a first emitting part;
a second emitting part disposed between the first emitting part and the second electrode; and
a first charge generation layer disposed between the first emitting part and the second emitting part,
wherein one of the first emitting part and the second emitting part comprises a first blue emitting material layer,
wherein another of the first emitting part and the second emitting part comprises:
a red emitting material layer comprising a first red host;
a yellow-green emitting material layer disposed between the red emitting part and the second electrode, and comprising a first yellow-green host; and
a green emitting material layer disposed between the yellow-green emitting material layer and the second electrode, and comprising a first green host,
wherein the first red host has an electron mobility in a range between about 1E-04 cm²/V·S and about 1E-03 cm²/V·S,
wherein the first yellow-green host has a hole mobility in a range between about 5E-08 cm²/V·S and about 1E-05 cm²/V·S, and
wherein the first green host has a hole mobility in a range between about 3E-05 cm²/V·S and about 1E-4 cm²/V·S.

14. The organic light emitting diode of claim 13, wherein the first red host comprises an organic compound having the following structure of Chemical Formula 1: 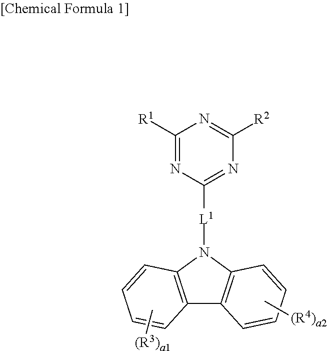
wherein, in Chemical Formula 1,
each of R¹ and R² is independently an unsubstituted or substituted C₆-C₃₀ aryl group or an unsubstituted or substituted C₃-C₃₀ hetero aryl group;
R³ is protium, deuterium or an unsubstituted or substituted C₁-C₂₀ alkyl group, where each R³ is identical to or different from each other when a1 is 2, 3 or 4;
R⁴ is each independently protium, deuterium or an unsubstituted or substituted C₁₂-C₃₀ hetero aryl group having a carbazolyl moiety, wherein one of R⁴s is the unsubstituted or substituted C₁₂-C₃₀ hetero aryl group having a carbazolyl moiety
L¹ is an unsubstituted or substituted C₆-C₃₀ arylene group;
a1 is 0, 1, 2, 3 or 4; and
a2 is 0, 1, 2, 3 or 4.

15. The organic light emitting diode of claim 13, wherein the first yellow-green host comprises an organic compound having the following structure of Chemical Formula 3: 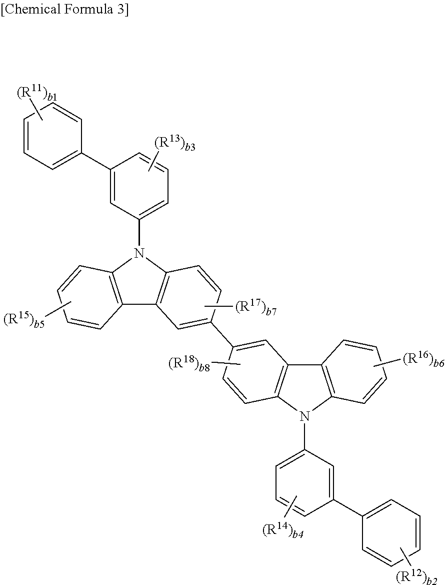
wherein, in Chemical Formula 3
each of R¹¹ to R¹⁸ is independently deuterium or an unsubstituted or substituted C₁-C₂₀ alkyl group, where at least one of R¹¹ to R¹⁸ is deuterium or a deuterium-substituted C₁-C₂₀ alkyl group, where each R¹¹ is identical to or different from each other when b1 is 2, 3, 4 or 5, where each R¹² is identical to or different from each other when b2 is 2, 3, 4 or 5, each R¹³ is identical to or different from each other when b3 is 2, 3 or 4, each R¹⁴ is identical to or different from each other when b4 is 2, 3 or 4, each R⁵ is identical to or different from each other when b5 is 2, 3 or 4, each R¹⁶ is identical to or different from each other when b6 is 2, 3 or 4, each R¹⁷ is identical to or different from each other when b7 is 2 or 3, and each R¹⁸ is identical to or different from each other when b8 is 2 or 3;
each of b1 and b2 is independently 0, 1, 2, 3, 4 or 5;
each of b3, b4, b5 and b6 is independently 0, 1, 2, 3 or 4; and
each of b7 and b8 is independently 0, 1, 2 or 3, where at least one of b1 to b8 is not 0.

16. The organic light emitting diode of claim 13, wherein the first green host comprises an organic compound having the following structure of Chemical Formula 5: 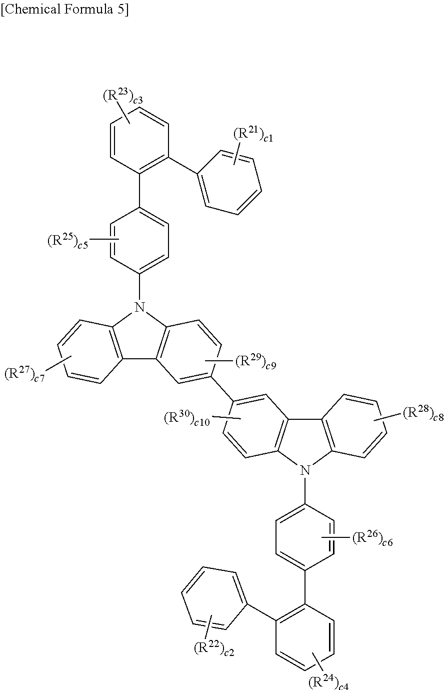
wherein, in Chemical Formula 5,
each of R²¹ to R³⁰ is independently deuterium or an unsubstituted or substituted C₁-C₂₀ alkyl group, where at least one of R² to R³⁰ is deuterium or a deuterium-substituted C₁-C₂₀ alkyl group, where each R²¹ is identical to or different from each other when c1 is 2, 3, 4 or 5, where each R²² is identical to or different from each other when c2 is 2, 3, 4 or 5, each R²³ is identical to or different from each other when c3 is 2, 3 or 4, each R²⁴ is identical to or different from each other when c4 is 2, 3 or 4, each R²⁵ is identical to or different from each other when c5 is 2, 3 or 4, each R²⁶ is identical to or different from each other when c6 is 2, 3 or 4, each R²⁷ is identical to or different from each other when c7 is 2, 3 or 4, each R²⁸ is identical to or different from each other when c8 is 2, 3 or 4, each R²⁹ is identical to or different from each other when c9 is 2 or 3, and each R³⁰ is identical to or different from each other when c10 is 2 or 3;
each of c1 and c2 is independently 0, 1, 2, 3, 4 or 5;
each of c3, c4, c5, c6, c7 and c8 is independently 0, 1, 2, 3 or 4; and
each of c9 and c10 is independently 0, 1, 2 or 3, where at least one of c1 to c10 is not 0.

17. The organic light emitting diode of claim 13, wherein the red emitting material layer has a thickness greater than a thickness of the yellow-green emitting material layer.

18. The organic light emitting diode of claim 13, wherein the green emitting material layer has a thickness equal to or greater than a thickness of the red emitting material layer.

19. The organic light emitting diode of claim 13, wherein the first emitting part comprises the first blue emitting material layer, and the second emitting part comprises the red emitting material layer, the yellow-green emitting material layer and the green emitting material layer.

20. The organic light emitting diode of claim 13, wherein the emissive layer further comprises:
a third emitting part disposed between the second emitting part and the second electrode; and
a second charge generation layer disposed between the second emitting part and the third emitting part,
wherein the first emitting part comprises the first blue emitting material layer,
wherein the second emitting part comprises the red emitting material layer, the yellow-green emitting material layer and the green emitting material layer, and
wherein the third emitting part comprises a second blue emitting material layer.

21. An organic light emitting device, comprising:
a substrate; and
the organic light emitting diode of claim 1 over the substrate.

22. An organic light emitting device, comprising:
a substrate; and
the organic light emitting diode of claim 13 over the substrate.
